(19) United States
(12) Patent Application Publication
(10) Pub. No.: US 2026/0118626 A1
(43) Pub. Date: Apr. 30, 2026

(54) TUNABLE OPTICAL SYSTEM

(71) Applicant: ASML Netherlands B.V., Veldhoven (NL)

(72) Inventors: Aniruddha Ramakrishna SONDE, Stamford, CT (US); Mahesh Upendra AJGAONKAR, Guilford, CT (US)

(73) Assignee: ASML Netherlands B.V., Veldhoven (NL)

(21) Appl. No.: 19/117,799

(22) PCT Filed: Sep. 15, 2023
(86) PCT No.: PCT/EP2023/075460

§ 371 Date: Apr. 2, 2025

Related U.S. Application Data
(60) Provisional application No. 63/412,822, filed on Oct. 3, 2022.

(51) Int. Cl. G02B 7/10; H10P 72/50

(52) U.S. Cl. CPC G02B 7/10; H10P 72/53

(57) ABSTRACT

Systems and methods for providing variable spot size and variable focus at a substrate are described. Sets of variable focal length lenses can be added to an alignment system to allow for adjustment of the spot size and focus. A variable focal length lens is a liquid lens that is tunable based on application of voltage across the lens. Toggling the voltage changes the water-oil interface in the liquid lens, which in turn changes the direction of light passing through. For example, turning on the voltage across the lens shifts the light output direction to converging at a focal point. As a result, variable focal length lenses provide adjustment to compensate for the fixed spot size and focus shortcomings of the prior art. Furthermore, variable focal length lenses can also be applied to compensate for spot shift and higher order diffraction orders.

### CROSS-REFERENCE TO RELATED APPLICATIONS

This application claims priority of U.S. application 63/412,822 which was filed on 3 Oct. 2022, and which is incorporated herein in its entirety by reference.

### TECHNICAL FIELD

The present disclosure relates to a tunable optical system.

### BACKGROUND

A lithographic apparatus is a machine that applies a desired pattern onto a target portion of a substrate. Lithographic apparatuses can be used, for example, in the manufacture of integrated circuits (ICs). In that circumstance, a patterning device, which is alternatively referred to as a mask or a reticle, may be used to generate a circuit pattern corresponding to an individual layer of the IC, and this pattern can be imaged onto a target portion (e.g., comprising part of, one or several dies) on a substrate (e.g., a silicon wafer) that has a layer of radiation-sensitive material (resist). In general, a single substrate will contain a network of adjacent target portions that are successively exposed. Known lithographic apparatuses include so-called steppers, in which each target portion is irradiated by exposing an entire pattern onto the target portion in one exposure, and so-called scanners, in which each target portion is irradiated by scanning the pattern through the beam in a given direction (the “scanning”-direction) while synchronously scanning the substrate parallel or anti parallel to this direction. It is also possible to transfer the pattern from the patterning device to the substrate by imprinting the pattern onto the substrate. Another lithographic system is an interferometric lithographic system where there is no patterning device, but rather a light beam is split into two beams, and the two beams are caused to interfere at a target portion of substrate through the use of a reflection system. The interference causes lines to be formed on at the target portion of the substrate.

During lithographic operation, different processing steps may require different layers to be sequentially formed on the substrate. Accordingly, it may be necessary to position the substrate relative to prior patterns formed thereon with a high degree of accuracy. Generally, alignment marks, which may comprise diffraction gratings for example, are placed on the substrate to be aligned, and are located with reference to a second object. A lithographic apparatus may use an alignment system for detecting positions of the alignment marks and for aligning the substrate using the alignment marks to ensure accuracy in subsequent lithographic operations, for example.

Alignment systems typically have their own illumination system that may be used to illuminate the alignment marks during alignment measurements. Determining alignment typically includes determining the position of an alignment mark (or marks) and/or other target in a layer of a semiconductor device structure. Alignment is typically determined by irradiating an alignment mark with radiation and comparing characteristics of different diffraction orders of radiation reflected from the alignment mark. Similar techniques are used to measure overlay and/or other parameters. Current alignment sensors have a single measurement illumination spot projected onto a substrate (e.g., a wafer). The single illumination spot is used for measurements of multiple alignment parameters, phase, and intensity detection. Current sensors measure metrology marks serially. Thus, the number of measured marks on a given substrate is limited by throughput considerations.

Alignment systems often use a dual self-referencing interferometer (SRI) system to acquire the intensity as a function of mark position. The phase of these sinusoidal signals is used to determine the alignment position of the mark. Each SRI has its dedicated polarization state, which is prepared using a feed optic, which separates the input light into the x and y polarization. These alignment systems are fixed optical systems.

Limitations in current alignment systems, however, are several. Beam spot sizes illuminating the target marks at the wafer are fixed. As a result, the size of the alignment mark is constrained. There may be alignment failure for relatively thick resists and/or warped wafers, for example. Another common problem is an undetectable Delta R effect, which is the reweighing of the diffraction beam numerical aperture due to product wafer stack. Additionally, mechatronic elements need to be used inside a typical optical module for higher order rejection. Mechatronics use mechanical elements that cause vibration and heat generation, and require a large amount of power, all of which are not desirable within an alignment system.

### SUMMARY

Disclosed are novel systems and methods that facilitate variable spot size and variable focus at a substrate for an alignment (and/or overlay) determination. Sets of variable focal length lenses are provided in an alignment system to allow for adjustment of the spot size and focus. A variable focal length lens is a liquid lens that is tunable based on application of voltage across the lens. Toggling the voltage changes the curvature of a water-oil interface in the liquid lens, which in turn changes the direction of light passing through. For example, turning on the voltage across the lens shifts the light output direction to converging at a focal point. As a result, variable focal length lenses provide adjustment to compensate for the fixed spot size and focus shortcomings of the prior art. Furthermore, variable focal length lenses can also be applied to compensate for spot shift and Delta R effects. Also, variable focal length lenses can be used in place of mechatronic elements to reject higher order diffraction orders.

According to an embodiment, a wafer alignment measurement system includes an illumination source, a radiation beam output from the illumination source, a first set of variable focal length lenses configured to receive the radiation beam, wherein the first set of variable focal length lenses are controllable to control an illumination spot size at a wafer, a second set of variable focal length lenses, and a third set of variable focal length lenses positioned in a pupil plane downstream of the objective system, wherein the third set of variable focal length lenses are controllable to control at least one of spot shift and higher order diffraction orders.

In an embodiment, the first set of variable focal length lenses are positioned in an illumination system.

In an embodiment, one first variable focal length lens is offset from an optical axis of the illumination source output.

In an embodiment, there are “N” output channels and “N+1” second variable focal length lenses, wherein there is one second variable focal length lens in each output channel and one second variable focal length lens in the objective system.

In an embodiment, the third set of variable focal length lenses is positioned in a pupil plane.

In an embodiment, the first, second, and third sets of variable focal length lenses are controllable by applying voltage to the first, second, and third sets of variable focal length lenses.

According to an embodiment, a wafer alignment measurement system includes an illumination source, a radiation beam output from the illumination source, and at least two variable focal length lenses configured to receive the radiation beam, wherein the variable focal length lenses are controllable to control an illumination spot size at a wafer.

In an embodiment, the variable focal length lenses are positioned in an illumination system

In an embodiment, the variable focus length lenses are positioned in the illumination system between an illumination relay lens and an aperture stop

In an embodiment, the variable focal length lenses are controllable by applying voltage to the variable focal length lenses.

In an embodiment, one variable focal length lens is offset from an optical axis of the illumination source output.

According to an embodiment, a wafer alignment measurement system includes an illumination source and at least two variable focal length lenses, one positioned in an output channel and another positioned in an objective system, wherein the variable focal length lenses are controllable to control a height of focus of the output from the objective system.

In an embodiment, the illumination source output is a radiation beam that reflects off the wafer.

In an embodiment, the radiation beam passes through the variable focal length lenses after reflecting off the wafer.

In an embodiment, there are “N” output channels and “N+1” variable focal length lenses, wherein there is one variable focal length lens in each output channel and one variable focal length lens in the objective system.

In an embodiment, the variable focal length lenses are controllable by applying voltage to the variable focal length lenses.

According to an embodiment, a wafer alignment measurement system includes an illumination source, a radiation beam output from the illumination source that travels to an objective system, and at least two variable focal length lenses positioned in a pupil plane downstream of the objective system, wherein the variable focal length lenses are controllable to control at least one of spot shift and higher order diffraction orders.

In an embodiment, the variable focal length lenses are positioned in a pupil plane.

In an embodiment, the variable focal length lenses are positioned in the pupil plane between the objective system and an output lens.

In an embodiment, the variable focal length lenses compensate for spot shift.

In an embodiment, the variable focal length lenses compensate for higher order diffraction orders

In an embodiment, the variable focal length lenses are controllable by applying voltage to the variable focal length lenses.

Further features and advantages of the invention, as well as the structure and operation of various embodiments of the invention, are described in detail below with reference to the accompanying drawings. It is noted that the invention is not limited to the specific embodiments described herein. Such embodiments are presented herein for illustrative purposes only. Additional embodiments will be apparent to persons skilled in the relevant art(s) based on the teachings contained herein.

### BRIEF DESCRIPTION OF THE DRAWINGS

The accompanying drawings, which are incorporated herein and form part of the specification, illustrate the present invention and, together with the description, further serve to explain the principles of the invention and to enable a person skilled in the relevant art(s) to make and use the invention.

FIG. 1A is a schematic illustration of a reflective lithographic apparatus, according to an embodiment of the present disclosure.

FIG. 1B is a schematic illustration of a transmissive lithographic apparatus, according to an embodiment of the present disclosure.

FIG. 1C is a more detailed schematic illustration of the reflective lithographic apparatus, according to an embodiment of the present disclosure.

FIG. 2A is a schematic illustration of a lithographic cell, according to an embodiment of the present disclosure.

FIG. 2B is a schematic illustration of an inspection system, according to an embodiment of the present disclosure.

FIG. 2C is a schematic illustration of a metrology technique, according to an embodiment of the present disclosure.

FIG. 2D is a schematic illustration of the relationship between a radiation illumination spot of an inspection system and a metrology target, according to an embodiment of the present disclosure.

FIG. 3 is a schematic illustration of a state-of-the-art alignment system, according to an embodiment of the present disclosure.

FIG. 4A is a schematic illustration of a variable focal length lens when no voltage is applied, according to an embodiment of the present disclosure.

FIG. 4B is a schematic illustration of a variable focal length lens when a non-zero voltage is applied, according to an embodiment of the present disclosure.

FIG. 4C is a schematic illustration of an illumination system of an alignment system for a variable spot size, according to an embodiment of the present disclosure.

FIG. 4D is a schematic illustration of an alignment system for a variable spot size, according to an embodiment of the present disclosure.

FIG. 4E is a schematic illustration of a radiation beam spot size for variable focal length lenses having nominal voltage for a variable spot size, according to an embodiment of the present disclosure.

FIG. 4F is a schematic illustration of a radiation beam spot size for variable focal length lenses having applied voltage for a variable spot size, according to an embodiment of the present disclosure.

FIG. 5A is a schematic illustration of an illumination system of an alignment system for beam steering, according to an embodiment of the present disclosure.

FIG. 5B is a schematic illustration of an alignment system for beam steering, according to an embodiment of the present disclosure.

FIG. 5C is a schematic illustration of the effects of an offset of a variable focal length lens for beam steering, according to an embodiment of the present disclosure.

FIG. 5D is another schematic illustration of the effects of an offset of a variable focal length lens for beam steering, according to an embodiment of the present disclosure.

FIG. 5E illustrates a combination view of elements shown in FIGS. 5A, 5C, and 5D, which form a portion of the system of FIG. 5B, according to an embodiment of the present disclosure.

FIG. 6A is a schematic illustration of an alignment system for variable focus, according to an embodiment of the present disclosure.

FIG. 6B is a schematic illustration of a thick resist substrate and variable focus, according to an embodiment of the present disclosure.

FIG. 6C is a schematic illustration of measuring overlay in a variable focus embodiment, according to an embodiment of the present disclosure.

FIG. 6D is another schematic illustration of measuring overlay in a variable focus embodiment, according to an embodiment of the present disclosure.

FIG. 7A is a schematic illustration of an alignment system for a spot shift and higher order rejection, according to an embodiment of the present disclosure.

FIG. 7B is a schematic illustration of calibrating a beam size in a spot shift embodiment, according to an embodiment of the present disclosure.

FIG. 7C is another schematic illustration of calibrating a beam size in a spot shift embodiment, according to an embodiment of the present disclosure.

FIG. 7D is another schematic illustration of calibrating a beam size in a spot shift embodiment, according to an embodiment of the present disclosure.

FIG. 7E is a schematic illustration of shifting higher diffraction orders in a higher order rejection embodiment, according to an embodiment of the present disclosure.

FIG. 8 illustrates a wafer alignment measurement method, according to an embodiment.

FIG. 9 is a block diagram of an example computer system, according to an embodiment.

### DETAILED DESCRIPTION

For semiconductor manufacturing and/or for other applications, a self-referencing interferometer (SRI) may be used in alignment systems to acquire the intensity of reflected radiation as a function of alignment mark position on a substrate (e.g., such as a wafer). The phase of these signals is used to determine the alignment position of a mark. However, there are limitations with the SRI approach. Beam spot sizes illuminating the alignment marks on the substrate are fixed, such that thick resists and/or warped substrates (e.g., wafers), for example, can inadvertently cause alignment failure. Also, with the SRI approach, mechatronic elements are often used within an optical module (OM) for higher order rejection, but these mechatronic elements can cause vibrations that lead to inaccurate measurements and/or other issues. In some embodiments, an optical module is comprised of a plurality of passive and active optical components which function to direct illumination such as light to a wafer under investigation. The optical module also collects diffracted light from a mark on the wafer and directs light towards a demultiplexer and optical detectors. For example, an optical module may illuminate a target on a wafer by directing light from a light source to the target, and collect a return signal. This return signal may be sent to detection electronics to calculate a target position on the wafer.

Among other advantages, the present systems and methods provide solutions for these and other problems that allow for variable spot size and smaller alignment marks. The present systems and methods also improve performance on thick stack measurements and allow for non-mechanical scanning within an OM. As described below, to provide a variable spot size, a typical input fiber assembly fixed lens is replaced with a set of liquid lenses to provide afocal functionality. Voltage applied to two variable focal length lenses provides increased focal length. In another embodiment, two variable focal length lenses are used to maintain a numerical aperture to account for thick stacks and maintain spot size at different focus.

By way of a brief introduction, the description below relates to semiconductor device manufacturing and patterning processes. The following paragraphs also describe several components of systems and/or methods for semiconductor device metrology. These systems and methods may be used for measuring alignment, overlay, etc., in a semiconductor device manufacturing process, for example, or for other operations.

### Example Reflective and Transmissive Lithographic Systems

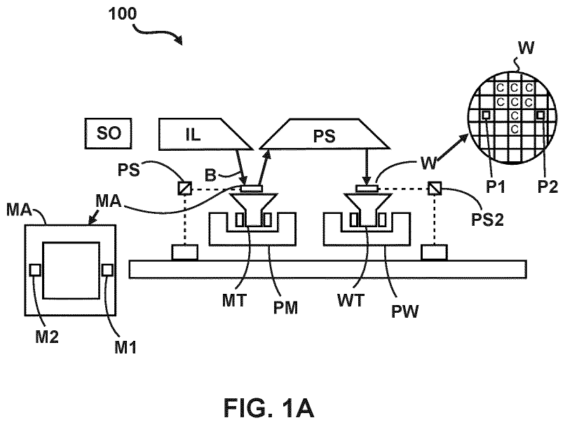

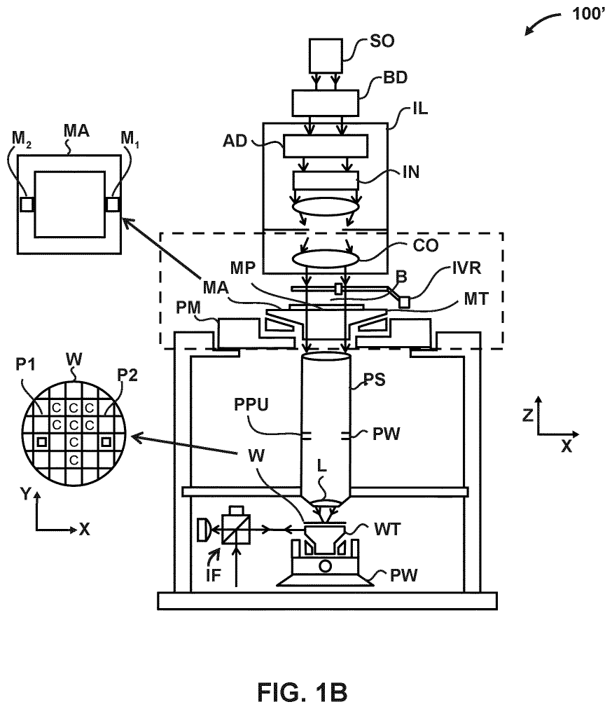

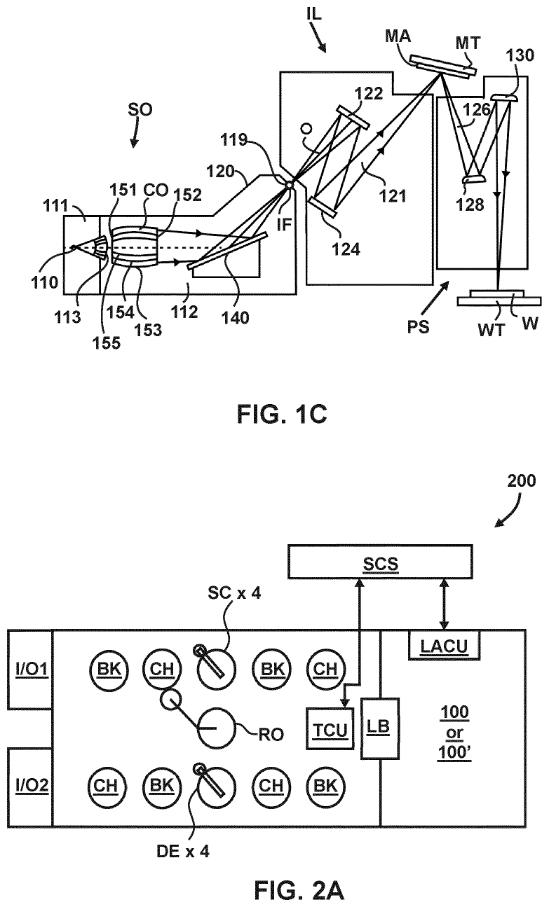

FIGS. 1A and 1B are schematic illustrations of a lithographic apparatus 100 and lithographic apparatus 100′, in or for which embodiments of the present disclosure may be implemented. Lithographic apparatus 100 and lithographic apparatus 100′ each include the following: an illumination system (illuminator) IL configured to condition a radiation beam B (for example, deep ultra violet or extreme ultra violet radiation); a support structure (for example, a mask table) MT configured to support a patterning device (for example, a mask, a reticle, or a dynamic patterning device) MA and connected to a first positioner PM configured to accurately position the patterning device MA; and, a substrate table (for example, a wafer table) WT configured to hold a substrate (for example, a resist coated wafer) W and connected to a second positioner PW configured to accurately position the substrate W. Lithographic apparatus 100 and 100′ also have a projection system PS configured to project a pattern imparted to the radiation beam B by patterning device MA onto a target portion (for example, comprising one or more dies) C of the substrate W. In lithographic apparatus 100, the patterning device MA and the projection system PS are reflective. In lithographic apparatus 100′, the patterning device MA and the projection system PS are transmissive.

The illumination system IL may include various types of optical components, such as refractive, reflective, catadioptric, magnetic, electromagnetic, electrostatic, or other types of optical components, or any combination thereof, for directing, shaping, or controlling the radiation beam B.

The support structure MT holds the patterning device MA in a manner that depends on the orientation of the patterning device MA with respect to a reference frame, the design of at least one of the lithographic apparatus 100 and 100′, and other conditions, such as whether or not the patterning device MA is held in a vacuum environment. The support structure MT may use mechanical, vacuum, electrostatic, or other clamping techniques to hold the patterning device MA. The support structure MT can be a frame or a table, for example, which can be fixed or movable, as required. By using sensors, the support structure MT can ensure that the patterning device MA is at a desired position, for example, with respect to the projection system PS.

The term “patterning device” MA should be broadly interpreted as referring to any device that can be used to impart a radiation beam B with a pattern in its cross-section, such as to create a pattern in the target portion C of the substrate W. The pattern imparted to the radiation beam B can correspond to a particular functional layer in a device being created in the target portion C to form an integrated circuit.

The patterning device MA may be transmissive (as in lithographic apparatus 100′ of FIG. 1B) or reflective (as in lithographic apparatus 100 of FIG. 1A). Examples of patterning devices MA include reticles, masks, programmable mirror arrays, and programmable LCD panels. Masks are well known in lithography, and include mask types such as binary, alternating phase shift, and attenuated phase shift, as well as various hybrid mask types. An example of a programmable mirror array employs a matrix arrangement of small mirrors, each of which can be individually tilted so as to reflect an incoming radiation beam in different directions. The tilted mirrors impart a pattern in the radiation beam B which is reflected by a matrix of small mirrors.

The term “projection system” PS can encompass any type of projection system, including refractive, reflective, catadioptric, magnetic, electromagnetic and electrostatic optical systems, or any combination thereof, as appropriate for the exposure radiation being used, or for other factors, such as the use of an immersion liquid on the substrate W or the use of a vacuum. A vacuum environment can be used for EUV or electron beam radiation since other gases can absorb too much radiation or electrons. A vacuum environment can therefore be provided to the whole beam path with the aid of a vacuum wall and vacuum pumps.

Lithographic apparatus 100 and/or lithographic apparatus 100′ can be of a type having two (dual stage) or more substrate tables WT (and/or two or more mask tables). In such “multiple stage” machines, the additional substrate tables WT can be used in parallel, or preparatory steps can be carried out on one or more tables while one or more other substrate tables WT are being used for exposure. In some situations, the additional table may not be a substrate table WT.

Referring to FIGS. 1A and 1B, the illuminator IL receives a radiation beam from a radiation source SO. The source SO and the lithographic apparatus 100, 100′ can be separate physical entities, for example, when the source SO is an excimer laser. In such cases, the source SO is not considered to form part of the lithographic apparatus 100 or 100′, and the radiation beam B passes from the source SO to the illuminator IL with the aid of a beam delivery system BD (in FIG. 1B) including, for example, suitable directing mirrors and/or a beam expander. In other cases, the source SO can be an integral part of the lithographic apparatus 100, 100′—for example when the source SO is a mercury lamp. The source SO and the illuminator IL, together with the beam delivery system BD, if required, can be referred to as a radiation system.

The illuminator IL can include an adjuster AD (in FIG. 1B) for adjusting the angular intensity distribution of the radiation beam. Generally, at least the outer and/or inner radial extent (commonly referred to as “σ-outer” and “σ-inner,” respectively) of the intensity distribution in a pupil plane of the illuminator can be adjusted. In addition, the illuminator IL can comprise various other components (in FIG. 1B), such as an integrator IN and a condenser CO. The illuminator IL can be used to condition the radiation beam B to have a desired uniformity and intensity distribution in its cross section.

Referring to FIG. 1A, the radiation beam B is incident on the patterning device (for example, mask) MA, which is held on the support structure (for example, mask table) MT, and is patterned by the patterning device MA. In lithographic apparatus 100, the radiation beam B is reflected from the patterning device (for example, mask) MA. After being reflected from the patterning device (for example, mask) MA, the radiation beam B passes through the projection system PS, which focuses the radiation beam B onto a target portion C of the substrate W. With the aid of the second positioner PW and position sensor IF2 (for example, an interferometric device, linear encoder, or capacitive sensor), the substrate table WT can be moved accurately (for example, so as to position different target portions C in the path of the radiation beam B). Similarly, the first positioner PM and another position sensor IF1 can be used to accurately position the patterning device (for example, mask) MA with respect to the path of the radiation beam B. Patterning device (for example, mask) MA and substrate W can be aligned using mask alignment marks M1, M2 and substrate alignment marks P1, P2.

Referring to FIG. 1B, the radiation beam B is incident on the patterning device (for example, mask MA), which is held on the support structure (for example, mask table MT), and is patterned by the patterning device. Having traversed the mask MA, the radiation beam B passes through the projection system PS, which focuses the beam onto a target portion C of the substrate W. The projection system has a pupil PPU conjugate to an illumination system pupil IPU. Portions of radiation emanate from the intensity distribution at the illumination system pupil IPU and traverse a mask pattern without being affected by diffraction at a mask pattern and create an image of the intensity distribution at the illumination system pupil IPU.

With the aid of the second positioner PW and position sensor IF (for example, an interferometric device, linear encoder, or capacitive sensor), the substrate table WT can be moved accurately (for example, so as to position different target portions C in the path of the radiation beam B). Similarly, the first positioner PM and another position sensor (not shown in FIG. 1B) can be used to accurately position the mask MA with respect to the path of the radiation beam B (for example, after mechanical retrieval from a mask library or during a scan).

In general, movement of the mask table MT can be realized with the aid of a long-stroke module (coarse positioning) and a short-stroke module (fine positioning), which form part of the first positioner PM. Similarly, movement of the substrate table WT can be realized using a long-stroke module and a short-stroke module, which form part of the second positioner PW. In the case of a stepper (as opposed to a scanner), the mask table MT can be connected to a short-stroke actuator only or can be fixed. Mask MA and substrate W can be aligned using mask alignment marks M1, M2, and substrate alignment marks P1, P2. Although the substrate alignment marks (as illustrated) occupy dedicated target portions, they can be located in spaces between target portions (known as scribe-lane alignment marks). Similarly, in situations in which more than one die is provided on the mask MA, the mask alignment marks can be located between the dies.

Mask table MT and patterning device MA can be in a vacuum chamber, where an in-vacuum robot IVR can be used to move patterning devices such as a mask in and out of vacuum chamber. Alternatively, when mask table MT and patterning device MA are outside of the vacuum chamber, an out-of-vacuum robot can be used for various transportation operations, similar to the in-vacuum robot IVR. Both the in-vacuum and out-of-vacuum robots need to be calibrated for a smooth transfer of any payload (e.g., mask) to a fixed kinematic mount of a transfer station.

The lithographic apparatus 100 and 100′ can be used in at least one of the following modes:
1. In step mode, the support structure (for example, mask table) MT and the substrate table WT are kept essentially stationary, while an entire pattern imparted to the radiation beam B is projected onto a target portion C at one time (i.e., a single static exposure). The substrate table WT is then shifted in the X and/or Y direction so that a different target portion C can be exposed.
2. In scan mode, the support structure (for example, mask table) MT and the substrate table WT are scanned synchronously while a pattern imparted to the radiation beam B is projected onto a target portion C (i.e., a single dynamic exposure). The velocity and direction of the substrate table WT relative to the support structure (for example, mask table) MT can be determined by the (de-)magnification and image reversal characteristics of the projection system PS.
3. In another mode, the support structure (for example, mask table) MT is kept substantially stationary holding a programmable patterning device, and the substrate table WT is moved or scanned while a pattern imparted to the radiation beam B is projected onto a target portion C. A pulsed radiation source SO can be employed and the programmable patterning device is updated as required after each movement of the substrate table WT or in between successive radiation pulses during a scan. This mode of operation can be readily applied to maskless lithography that utilizes a programmable patterning device, such as a programmable mirror array.

Combinations and/or variations on the described modes of use or entirely different modes of use can also be employed.

In some embodiments, lithographic apparatus 100 includes an extreme ultraviolet (EUV) source, which is configured to generate a beam of EUV radiation for EUV lithography. In general, the EUV source is configured in a radiation system, and a corresponding illumination system is configured to condition the EUV radiation beam of the EUV source.

FIG. 1C shows the lithographic apparatus 100 in more detail, including the source collector apparatus SO, the illumination system IL, and the projection system PS. The source collector apparatus SO is constructed and arranged such that a vacuum environment can be maintained in an enclosing structure 120 of the source collector apparatus SO. An EUV radiation emitting plasma 110 may be formed by a discharge produced plasma source. EUV radiation may be produced by a gas or vapor, for example Xe gas, Li vapor or Sn vapor in which the hot plasma 110 is created to emit radiation in the EUV range of the electromagnetic spectrum. The hot plasma 110 is created by, for example, an electrical discharge causing an at least partially ionized plasma. Partial pressures of, for example, 10 Pa of Xe, Li, Sn vapor or any other suitable gas or vapor may be required for efficient generation of the radiation. In an embodiment, a plasma of excited tin (Sn) is provided to produce EUV radiation.

The radiation emitted by the hot plasma 110 is passed from a source chamber 111 into a collector chamber 112 via an optional gas barrier or contaminant trap 113 (in some cases also referred to as contaminant barrier or foil trap) which is positioned in or behind an opening in source chamber 111. The contaminant trap 113 may include a channel structure. Contamination trap 113 may also include a gas barrier or a combination of a gas barrier and a channel structure. The contaminant trap 113 further indicated herein at least includes a channel structure, as known in the art.

The collector chamber 112 may include a radiation collector CO which may be a so-called grazing incidence collector. Radiation collector CO has an upstream radiation collector side 151 and a downstream radiation collector side 152. Radiation that traverses collector CO can be reflected off a grating spectral filter 140 to be focused in a virtual source point IF. The virtual source point IF is commonly referred to as the intermediate focus, and the source collector apparatus is arranged such that the intermediate focus IF is located at or near an opening 119 in the enclosing structure 120. The virtual source point IF is an image of the radiation emitting plasma 110. Grating spectral filter 140 is used in particular for suppressing infra-red (IR) radiation.

Subsequently the radiation traverses the illumination system IL, which may include a facetted field mirror device 122 and a facetted pupil mirror device 124 arranged to provide a desired angular distribution of the radiation beam 121, at the patterning device MA, as well as a desired uniformity of radiation intensity at the patterning device MA. Upon reflection of the radiation beam 121 at the patterning device MA, held by the support structure MT, a patterned beam 126 is formed and the patterned beam 126 is imaged by the projection system PS via reflective elements 128, 130 onto a substrate W held by the wafer stage or substrate table WT.

More elements than shown may generally be present in illumination optics unit IL and projection system PS. The grating spectral filter 140 may optionally be present, depending upon the type of lithographic apparatus. Further, there may be more mirrors present than those shown in the FIGS., for example there may be 1-6 additional reflective elements present in the projection system PS than shown in FIG. 1C.

Collector optic CO, as illustrated in FIG. 1C, is depicted as a nested collector with grazing incidence reflectors 153, 154 and 155, just as an example of a collector (or collector mirror). The grazing incidence reflectors 153, 154 and 155 are disposed axially symmetric around an optical axis O and a collector optic CO of this type is preferably used in combination with a discharge produced plasma source, often called a DPP source.

### Example Lithographic Cell

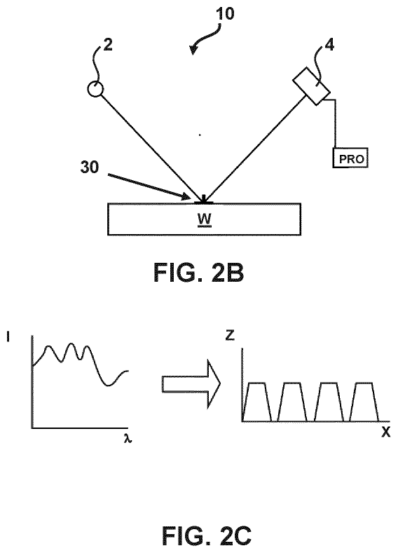

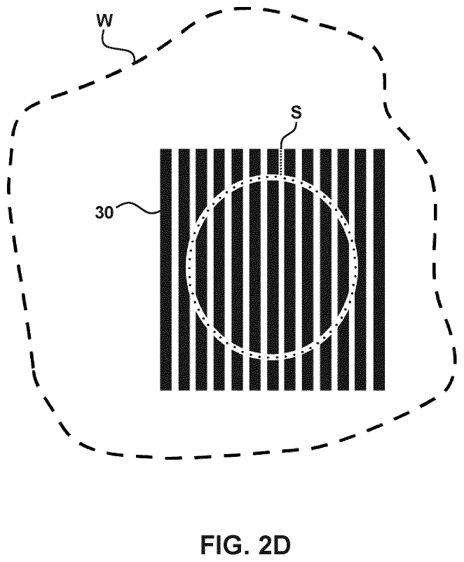

FIG. 2A shows a lithographic cell 200, also sometimes referred to a lithocell or cluster. Lithographic apparatus 100 or 100′ may form part of lithographic cell 200. Lithographic cell 200 may also include apparatus to perform pre- and post-exposure processes on a substrate. Conventionally these include spin coaters SC to deposit resist layers, developers DE to develop exposed resist, chill plates CH and bake plates BK. A substrate handler, or robot, RO picks up substrates from input/output ports I/O1, I/O2, moves them between the different process apparatus and delivers then to the loading bay LB of the lithographic apparatus. These devices, which are often collectively referred to as the track, are under the control of a track control unit TCU which is itself controlled by the supervisory control system SCS, which also controls the lithographic apparatus via lithography control unit LACU. Thus, the different apparatus can be operated to maximize throughput and processing efficiency.

A manufacturing facility in which lithographic cell 200 is located also typically includes a metrology system that measures some or all of the substrates W (FIGS. 1A, 1B, 1C)) that have been processed in the lithocell or other objects in the lithocell. The metrology system may be part of the lithocell, for example, or it may be part of the lithographic apparatus. One or more measured parameters may include, for example, alignment, overlay between successive layers formed in or on a patterned substrate, critical dimension (CD) (e.g., critical linewidth) of, for example, features formed in or on the patterned substrate, focus or focus error of an optical lithography step, dose or dose error of an optical lithography step, optical aberrations of an optical lithography step, etc. This measurement is often performed on one or more dedicated metrology targets provided on the substrate. The measurement can be performed after-development of a resist but before etching, after-etching, after deposition, and/or at other times.

There are various techniques for making measurements of the structures formed in the patterning process, including the use of a scanning electron microscope, an image-based measurement tool and/or various specialized tools. A fast and non-invasive form of specialized metrology tool is one in which a beam of radiation is directed onto a target on the surface of the substrate and properties of the scattered (diffracted/reflected) beam are measured. By evaluating one or more properties of the radiation scattered by the substrate, one or more properties of the substrate can be determined. Traditionally, this may be termed diffraction-based metrology. Applications of this diffraction-based metrology include the measurement of alignment, overlay, etc. For example, alignment and/or overlay can be measured by comparing parts of the diffraction spectrum (for example, comparing different diffraction orders in the diffraction spectrum of a periodic grating).

Thus, in a device fabrication process (e.g., a patterning process or a lithography process), a substrate or other objects may be subjected to various types of measurement during or after the process. The measurement may determine whether a particular substrate is defective, may establish adjustments to the process and apparatuses used in the process (e.g., aligning two layers on the substrate or aligning the patterning device to the substrate), may measure the performance of the process and the apparatuses, or may be for other purposes. Examples of measurement include optical imaging (e.g., optical microscope), non-imaging optical measurement (e.g., measurement based on diffraction such as the ASML YieldStar metrology tool, the ASML SMASH metrology system), mechanical measurement (e.g., profiling using a stylus, atomic force microscopy (AFM)), and/or non-optical imaging (e.g., scanning electron microscopy (SEM)).

Metrology results may be provided directly or indirectly to the supervisory control system SCS. If an error is detected, an adjustment may be made to exposure of a subsequent substrate (especially if the inspection can be done soon and fast enough that one or more other substrates of the batch are still to be exposed) and/or to subsequent exposure of the exposed substrate. Also, an already exposed substrate may be stripped and reworked to improve yield, or discarded, thereby avoiding performing further processing on a substrate known to be faulty. In a case where only some target portions of a substrate are faulty, further exposures may be performed only on those target portions which meet specifications. Other manufacturing process adjustments are contemplated.

A metrology system may be used to determine one or more properties of the substrate structure, and in particular, how one or more properties of different substrate structures vary, or different layers of the same substrate structure vary from layer to layer. The metrology system may be integrated into the lithographic apparatus 100 or 100′, or the lithographic 200, or may be a stand-alone device.

### Alignment System Embodiment

One or more targets may be specifically provided on the substrate to enable alignment. Typically, the target is specially designed and may comprise a periodic structure. For example, the target on a substrate may comprise one or more 1-D periodic structures (e.g., geometric features such as gratings), which are printed such that after development, the periodic structural features are formed of solid resist lines. As another example, the target may comprise one or more 2-D periodic structures (e.g., gratings), which are printed such that after development, the one or more periodic structures are formed of solid resist pillars or vias in the resist. The bars, pillars, or vias may alternatively be etched into the substrate (e.g., into one or more layers on the substrate).

FIG. 2B depicts an example alignment system 10 that may be used to detect alignment as well as overlay and/or perform other metrology operations. It comprises a radiation or illumination source 2 which projects or otherwise irradiates radiation onto a substrate W (e.g., which may typically include a metrology mark). The redirected radiation is passed to a sensor such as a spectrometer detector 4 and/or other sensors, which measures a spectrum (intensity as a function of wavelength) of the specular reflected and/or diffracted radiation, as shown, e.g., in the graph on the left of FIG. 2C. The sensor may generate an alignment signal conveying alignment data indicative of properties of the reflected radiation. From this data, the structure or profile giving rise to the detected spectrum may be reconstructed by one or more processors PRO, a generalized example of which is shown in FIG. 2C, or by other operations.

As in the lithographic apparatus 100 and 100′ of FIGS. 1A and 1B, one or more substrate tables may be provided to hold the substrate W during measurement operations. The one or more substrate tables may be similar or identical in form to the substrate table WT of FIGS. 1A and 1B. In an example where inspection system 10 is integrated with the lithographic apparatus, they may even be the same substrate table. Coarse and fine positioners may be provided and configured to accurately position the substrate in relation to a measurement optical system. Various sensors and actuators are provided, for example, to acquire the position of a target portion of interest of a structure (e.g., a metrology mark), and to bring it into position under an objective lens. Typically, many measurements will be made on target portions of a structure at different locations across the substrate W. The substrate support can be moved in X and Y directions to acquire different targets, and in the Z direction to obtain a desired location of the target portion relative to the focus of the optical system. It is convenient to think and describe operations as if the objective lens is being brought to different locations relative to the substrate, when, for example, in practice the optical system may remain substantially stationary (typically in the X and Y directions, but perhaps also in the Z direction) and the substrate moves. Provided the relative position of the substrate and the optical system is correct, it does not matter in principle which one of those is moving, or if both are moving, or a combination of a part of the optical system is moving (e.g., in the Z and/or tilt direction) with the remainder of the optical system being stationary and the substrate is moving (e.g., in the X and Y directions, but also optionally in the Z and/or tilt direction).

For typical alignment measurements, a target (portion) 30 on substrate W may be a 1-D grating, which is printed such that after development, the bars are formed of solid resist lines (e.g., which may be covered by a deposition layer), and/or other materials. Or the target 30 may be a 2-D grating, which is printed such that after development, the grating is formed of solid resist pillars, and/or other features in the resist.

The bars, pillars, vias, and/or other features may be etched into or on the substrate (e.g., into one or more layers on the substrate), deposited on a substrate, covered by a deposition layer, and/or have other properties. Target (portion) 30 (e.g., of bars, pillars, vias, etc.) is sensitive to changes in processing in the patterning process (e.g., optical aberration in the lithographic projection apparatus such as in the projection system, focus change, dose change, etc.) such that process variation manifests in variation in target 30. Accordingly, the measured data from target 30 may be used to determine an adjustment for one or more of the manufacturing processes, and/or used as a basis for making the actual adjustment.

For example, the measured data from target 30 may indicate overlay for a layer of a semiconductor device. The measured data from target 30 may be used (e.g., by the one or more processors PRO and/or other processors) for determining one or more semiconductor device manufacturing process parameters based on the overlay and determining an adjustment for a semiconductor device manufacturing apparatus based on the one or more determined semiconductor device manufacturing process parameters. In some embodiments, this may comprise a stage position adjustment, for example, or this may include determining an adjustment for a mask design, a metrology target design, a semiconductor device design, an intensity of the radiation, an incident angle of the radiation, a wavelength of the radiation, a pupil size and/or shape, a resist material, and/or other process parameters.

FIG. 2D illustrates a plan view of a typical target (e.g., metrology mark) 30, and the extent of a typical radiation illumination spot S. Typically, to obtain a diffraction spectrum that is free of interference from surrounding structures, the target 30, in an embodiment, is a periodic structure (e.g., grating) larger than the width (e.g., diameter) of the illumination spot S. The width of spot S may be smaller than the width and length of the target. The target, in other words, is ‘underfilled’ by the illumination, and the diffraction signal is essentially free from any signals from product features and the like outside the target itself. The illumination arrangement may be configured to provide illumination of a uniform intensity across a back focal plane of an objective, for example. Alternatively, by, for example, including an aperture in the illumination path, illumination may be restricted to on-axis or off-axis directions.

### State of the Art Alignment System

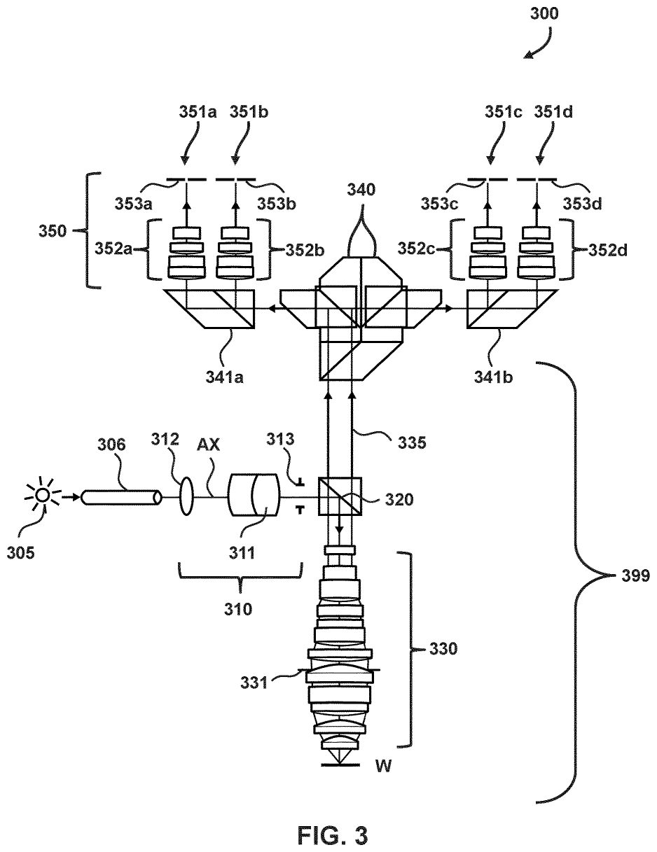

FIG. 3 illustrates a schematic of a state-of-the-art alignment system 300 that can be implemented as a part of or otherwise in conjunction with lithographic apparatus 100 or 100′, and/or other lithographic apparatuses, according to an embodiment. In an example of this embodiment, alignment system 300 may be configured to align a substrate (e.g., a semiconductor wafer, substrate W described above, etc.) with respect to a patterning device (e.g., patterning device MA described above). Alignment system 300 may be further configured to detect positions of alignment marks on the substrate and to align the substrate with respect to the patterning device or other components of lithographic apparatus 100 or 100′ using the detected positions of the alignment marks. Such alignment of the substrate may ensure accurate exposure of one or more patterns on the substrate.

According to an embodiment, alignment system 300 may include an illumination source 305, an input fiber 307, an illumination system 310, a spot mirror 320, an objective 330, self-referencing interferometers (SRI) 340, polarizing beam splitters 341a and 341b, and output system 350. An optical module 399 of system 300 may include any optical components in or along a radiation pathway that are used to direct or control radiation in system 300. Illumination source 305 may be configured to provide an electromagnetic narrow band radiation beam 306 having a first polarization state, such as a linear polarization state. In an example, the narrow band radiation beam 306 may be within a spectrum of wavelengths between about 500 nm to about 900 nm. In another example, the narrow band radiation beam 306 comprises discrete narrow passbands within a spectrum of wavelengths between about 500 nm to about 900 nm. Yet in another example, radiation beam 306 may be monochromatic, for example, provided by a monochromatic light source, such as a laser light source in illumination source 305. Polychromatic light sources such as LEDs may also be used in illumination source 305 to provide a polychromatic radiation beam 306.

Illumination system 310 may be configured to receive radiation beam 306. In an example of this embodiment, illumination system 310 may be further configured to direct radiation beam 306 onto a substrate W. Illumination system 310 may include an illumination relay lens 312, a fixed lens input fiber assembly (IFA) 311, and an aperture stop 313. Illumination system 310 may also include optics that create additional illumination beams split or replicated from radiation beam 306 and direct them towards an alignment mark (not shown) on substrate W.

Substrate W may be placed on a stage WT (see FIGS. 1A, 1B, and 1C) moveable along a direction. Radiation beam 306 may be configured to illuminate the alignment mark located on substrate W. The alignment mark may be coated with a radiation sensitive film in an example of this embodiment. In another example, the alignment mark may have 180° symmetry. That is, when the alignment mark is rotated 180° about an axis of symmetry perpendicular to a plane of the alignment mark, rotated alignment mark may be substantially identical to an unrotated alignment mark.

As illustrated in FIG. 3, objective 330 may be configured to direct diffracted radiation beam 335 towards self-referencing interferometers 340, according to an embodiment. Objective 330 may comprise any appropriate number of optical elements suitable for directing diffracted radiation beam 335. Objective 330 may also include a field stop 331. In an example embodiment, diffracted radiation beam 335 may be at least a portion of radiation beam 306 that is diffracted from an alignment mark. Spot mirror 320 may be substantially transparent to diffracted radiation beam 335 and may allow diffracted radiation beam 335 to pass through it without substantially changing the properties of diffracted radiation beam 335. It should be further noted that even though objective 330 is shown to direct radiation beam 335 towards self-referencing interferometers 340, the disclosure is not so limiting. Other optical arrangements may be used to obtain the similar result of detecting diffraction signals from the alignment mark.

In some embodiments, self-referencing interferometers 340 may comprise any appropriate set of optical elements, for example, a combination of prisms, half wave plates, and compensators that may be configured to form two images of alignment mark based on the received diffracted radiation beam 335. It should be appreciated that a good quality image need not be formed, but that the features of alignment mark should be resolved. self-referencing interferometers 340 may be further configured to rotate one of the two images with respect to the other of the two images 180° and recombine the rotated and unrotated images interferometrically.

After passing through self-referencing interferometers 340, diffracted radiation beam 335 in incident upon polarizing beam splitters 341a and 341b. Polarizing beam splitters 341a and 341b redirect diffracted radiation beam 335 to output system 350. First output channel 351a comprises output lenses 352a and output field stop 353a for passing the diffracted beam 335 to a detector (not shown) for measuring the sum of the beam's y-components. Second output channel 351b comprises output lenses 352b and output field stop 353b and a second detector (not shown) for measuring the difference of the beam's y-components. Third output channel 351c comprises output lenses 352c and output field stop 353c and a third detector (not shown) for measuring the sum of the beam's x-components. Fourth output channel 351d comprises output lenses 352d and output field stop 353d and a fourth detector (not shown) for measuring the difference of the beam's x-components.

The detectors described above may be configured to receive the recombined image and detect an interference as a result of the recombined image when an alignment axis of alignment system 300 passes through a center of symmetry (not shown) of alignment mark. Such interference may be due to alignment mark being 180° symmetrical, and the recombined image interfering constructively or destructively, according to an example embodiment. Based on the detected interference, detectors may be further configured to determine a position of the center of symmetry of alignment mark and consequently, detect a position of substrate W. According to an example, alignment axis may be aligned with an optical beam perpendicular to substrate 420 and passing through a center of self-referencing interferometers 340.

### Variable Focal Length Lenses

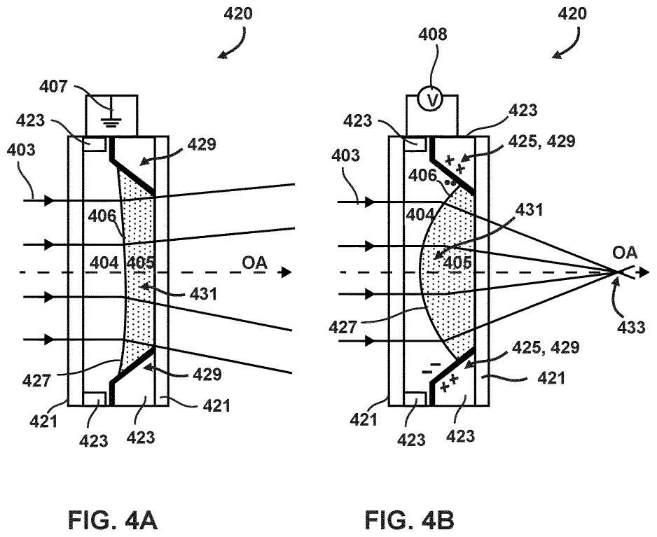

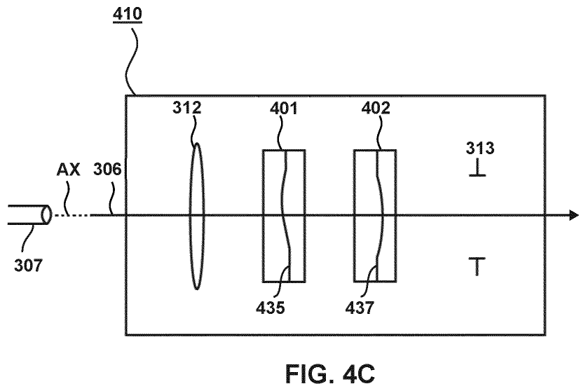

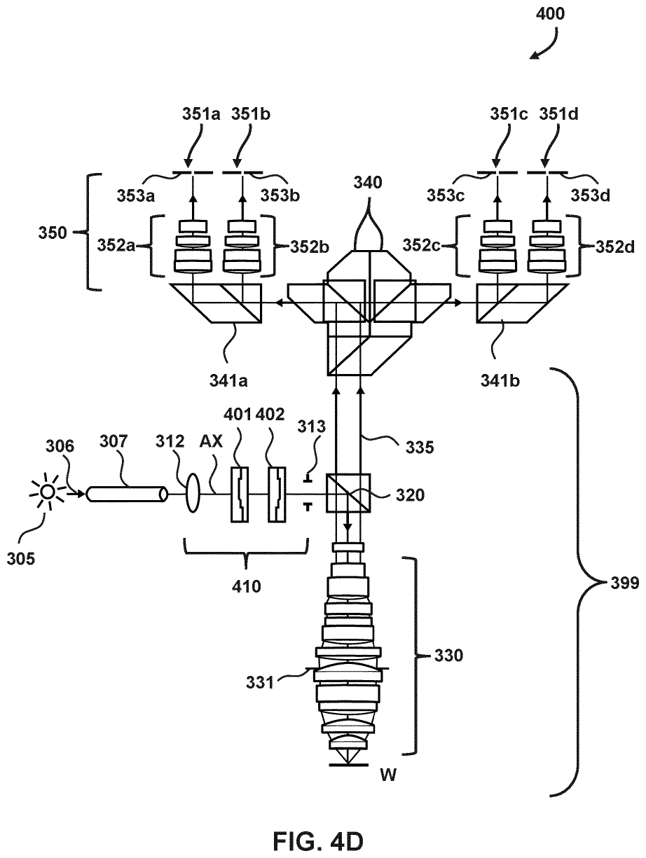

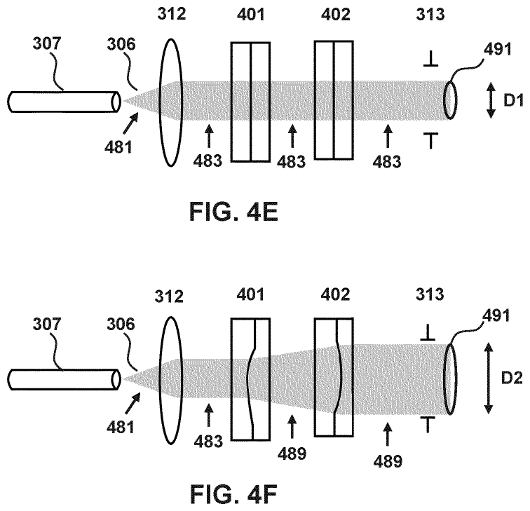

FIGS. 4A-4B illustrate a schematic of a variable focal length lens 420. Lens 420 is shown in “off” (FIG. 4A) and “on” (FIG. 4B) configurations, as described below. The variable focal length lens 420 is a liquid lens comprising water 404 and oil 405 and forming a water-oil interface 406, with an interface membrane 427 forming a seal therebetween. FIGS. 4A and 4B also illustrate other components of lens 420, including an optical window 421 configured to transmit light beams 403 (and/or other radiation), metal structural components 423, and electrostatic pressure 425 provided when lens 420 is “on” (FIG. 4B).

A focal length of the lens 420 can be finely tuned and modified by applying a specified voltage 408 thereto. FIG. 4A shows the water-oil interface 406 when no voltage is applied (“off”). No voltage applied is shown in FIG. 4A as the lens 420 being connected to ground 407. In one example, with no voltage, the water 404 and oil 405 naturally form a slightly concave curvature at the interface 406, causing incident light beams 403 that are parallel to optical axis OA to slightly diverge when exiting variable focal length lens 420. As another example, FIG. 4B shows the water-oil interface 406 when a non-zero voltage 408 is applied (“on”). The applied voltage 408 in the liquid lens 420 creates electrostatic pressure 425 at or near the edges 429, creating a buildup of positive charges (see “+” symbols labeled in FIG. 4B). As a result, negative charges (see “−” symbols labeled in FIG. 4B) within the water 404 are attracted to the positive charges. Consequently, water 404 moves to the edge 429 of the lens 420, which displaces the oil 405 into the center 431 of the lens 420. FIG. 4B shows that the curvature of the interface 406 has now changed to a convex shape, which converges the incident light beams 403 to a focal point 433 on optical axis OA.

The variable focal length lens 420 may replace (as described below) an input fiber assembly in a typical state of the art alignment system (e.g., system 300 described above). Compared to typical state of the art alignment systems, the variable focal length lens 420 described herein provides a quick response (e.g., on the order of milliseconds), having a compact design, low heat dissipation at the lens, low power consumption of roughly 1 mW (+/−20%) and allows for the tunability of optical module 399 functionality, among other advantages.

### Variable Spot Size Alignment System

FIG. 4C illustrates variable focal length lenses 401 and 402 (e.g., each similar to and/or the same as focal length lens 420 described above) incorporated into an illumination system 410. Illumination system 410 may be part of a variable spot size alignment system 400 as shown in FIG. 4D. As shown in FIG. 4D, the illumination system 310 of FIG. 3 is replaced by the illumination system 410 of FIG. 4C. In one embodiment, variable spot size alignment system 400 (as shown in FIG. 4D) utilizes the remainder of the components of the alignment system 300 of FIG. 3. In the illumination system 410 of FIG. 4C, the illumination system variable focal lenses 401 and 402 replace the fixed lens IFA 311 of the illumination system 310 of FIG. 3. By removing IFA 311 and inserting lenses 401 and 402, alignment system 400 can achieve variable spot size at substrate W.

According to an embodiment, illumination system 410 (as shown in FIGS. 4C and 4D) is configured to receive radiation beam 306, for example, from an input fiber 307 along an optical axis AX (optical axis AX may be similar to and/or the same as optical axis OA described above). Illumination system 410 includes a fixed lens, such as an illumination relay lens 312, that receives radiation beam 306, before radiation is passed to the first variable focal length lens 401, and then to the second variable focal length lens 402, before reaching an aperture stop 313.

The set of variable focal length lenses (in this case a pair of variable focal length lenses 401 and 402) are typically used in pairs to manipulate the focal length. However, a set of variable focal length lenses is not limited to two lenses.

In one embodiment, a nominal amount of voltage is applied to the variable focal length lenses 401 and 402 to achieve no curvature of the membrane(s) 435, 437 (similar to and/or the same as membrane 427 described above). When an increased voltage is applied, in one embodiment, an increased focal length is achieved, and a spot size of radiation on a substrate changes. The configuration can be such that a negative voltage is applied to achieve a decreased focal length (and a different spot size of radiation on the substrate). The polarity of the voltage to achieve different curvatures to increase or decrease focal length can be reversed if desired.

FIG. 4D illustrates input fiber assembly (IFA) 311 from FIG. 3 replaced by illumination system 410 shown in FIG. 4C. By replacing the input fiber assembly (IFA) 311 with the illumination system 410, including the variable focal length lenses 401 and 402, a variable spot size on substrate W can be realized. The spot size on substrate W can be enlarged or shrunk by applying different voltages across the lenses 401, 402. Depending on the size of the alignment mark, the spot size can be enlarged or reduced. By using the voltage described above to vary a spot size of radiation on a substrate to conform to the size of an alignment (or other metrology) mark, alignment marks of various sizes can be more easily measured.

Spot 491 size variation is illustrated in FIGS. 4E and 4F. FIG. 4E illustrates a schematic of the spot 491 size of the radiation beam 306 when nominal voltage is applied to variable focal length lenses 401 and 402. Upon exiting the input fiber 307, the radiation beam 306 expands 481 in size until it reaches illumination relay lens 312. The illumination relay lens 312 changes the incoming beam to a parallel radiation beam 483. With a nominal voltage applied to each of the variable focal length lenses 401 and 402, there is no curvature in the water-oil interface 406 (see FIGS. 4A and 4B) for the lenses 401 and 402. As a result, the parallel radiation beam 306 remains the same upon exiting each lens 401 and 402. Then the parallel radiation beam 306 travels through the aperture stop 313 and spot 491 has a diameter D1.

FIG. 4F illustrates a schematic of the spot 491 size of the radiation beam 306 when voltage is applied to variable focal length lenses 401 and 402. Similar to FIG. 4E, upon exiting the input fiber 307, the radiation beam 306 expands 481 in size until it reaches illumination relay lens 312. The illumination relay lens 312 changes the incoming beam to a parallel radiation beam 483. With the application of voltage to each of the variable focal length lenses 401 and 402, a curvature is formed at the water-oil interface 406 (see FIGS. 4A and 4B) for the lenses 401 and 402. As a result, the increased focal length of the lenses 401 and 402 increases 489 the size of the parallel radiation beam 306 upon exiting the second lens 402. Finally, the enlarged radiation beam 306 travels through the aperture stop 313, and spot 491 has an enlarged diameter D2.

Currently, state of the art alignment systems such as system 300 shown in FIG. 3 can achieve an illumination spot size as small as approximately 30 um to measure alignment marks of 30 um×80 um. However, by using the illumination system 410 of FIG. 4C in an alignment system having variable spot size, a variable spot size that can be fine-tuned to be in the range of 10 um to 40 um or less can be achieved to measure alignment marks as small as 10 um×10 um or less.

### Beam Steering Alignment System

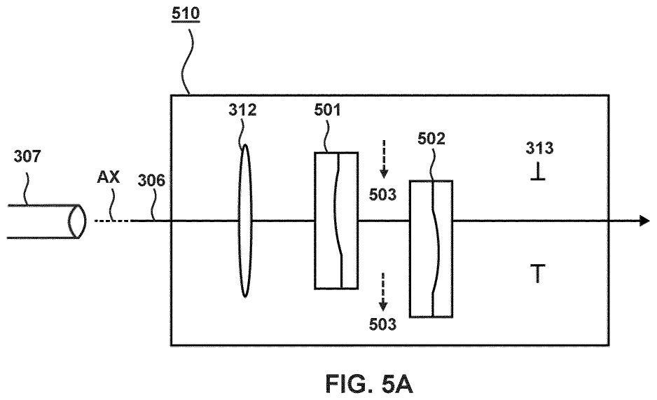

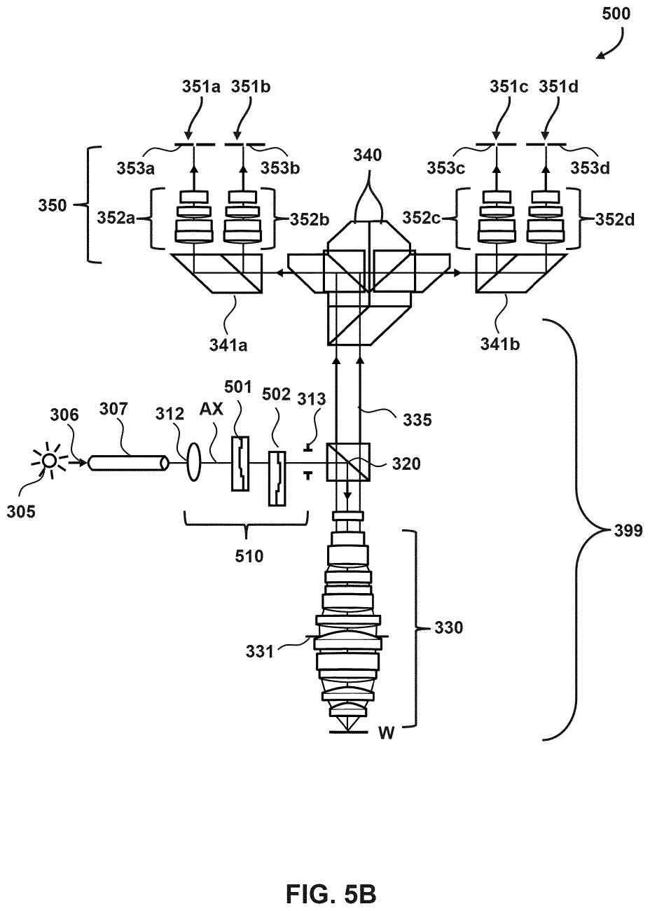

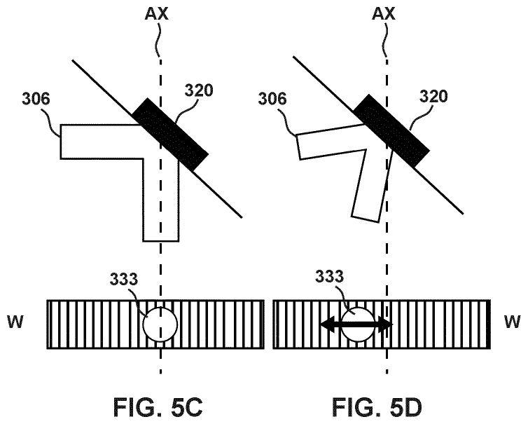

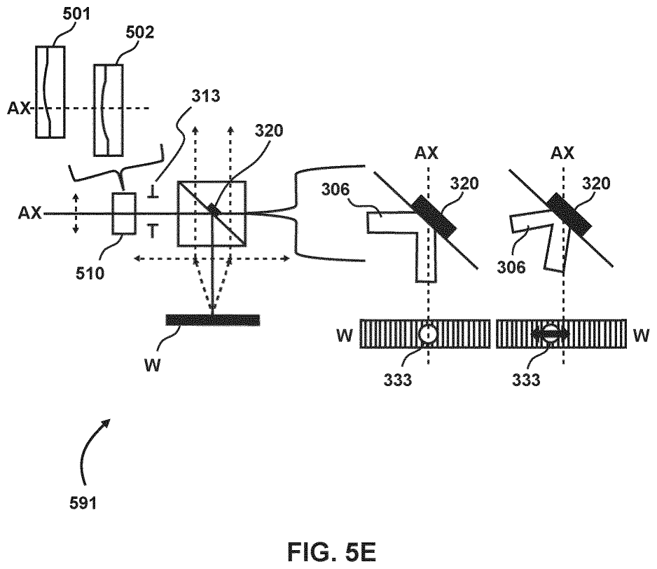

FIG. 5A illustrates a schematic of an illumination system 510 of a beam steering alignment system. Illumination system 510 includes a relay lens 312 (e.g., similar to and/or the same as relay lens 312 shown in FIG. 4C), first and second variable focal length lenses 501 and 502 (similar to and/or the same as lenses 401 and 402 shown in FIG. 4C), and an aperture stop 313 (similar to and/or the same as aperture stop 313 shown in FIG. 4C). As shown in FIG. 5A, illumination system 510 may be configured to receive radiation beam 306 from fiber 307. Illumination system 510 includes an illumination relay lens 312 that receives radiation beam 306, a first variable focal length lens 501, a second variable focal length lens 502, and an aperture stop 313. Second variable focal length lens 502 is offset 503 from first variable focal length lens 501 and optical axis AX.

FIG. 5B illustrates a beam steering alignment system 500 that includes illumination system 510. In FIG. 5B, illumination system 310 shown in FIG. 3 is replaced with the illumination system 510 of FIG. 5A. In one embodiment, beam steering alignment system 500 (as shown in FIG. 5B) utilizes the remainder of the components of the alignment system 300 of FIG. 3.

FIGS. 5C-5D illustrate a schematic of the effects of variable focal length lens 502 being offset from optical axis AX. FIG. 5C illustrates that when variable focal length lens 502 is not offset from optical axis AX, illumination spot 333 on substrate W coincides with optical axis AX. On the other hand, FIG. 5D illustrates that when variable focal length lens 502 is offset from optical axis AX, illumination spot 333 on substrate W also becomes offset from optical axis AX. An offset from optical axis AX of variable focal length lens 502 leads radiation beam 306 to reflect off spot mirror 320 at a different angle, which in turn leads to an illumination spot 333 that is offset from optical axis AX, as shown in FIG. 5D. For example, a beam steering angle of 1.8 mrad tilt results in a ±24 um scan length.

By offsetting variable focal length lens 502 from optical axis AX, the beam can be shifted laterally at substrate W. In beam steering, substrate W is stationary while lens 502 is moved, which in turn alters beam 306. The beam can be steered in the x and/or y direction. Beam steering can be used to compensate lateral scan offset due to substrate table WT (substrate table WT is shown and described above). Because beam steering is easier to perform compared to accelerating and decelerating substrate table WT, beam steering can be used to measure alignment. As a result, beam steering can be used to perform an alignment diagnostic. Further, beam steering allows non-mechanical scanning within the optical module 399 (see FIG. 5B).

For clarity, FIG. 5E illustrates a combination view 591 of elements shown in FIGS. 5A, 5C, and 5D, which form a portion of the larger alignment system 500 of FIG. 5B. For example, FIG. 5E illustrates tunable lenses 501 and 502, with lens 502 offset from optical axis AX and lens 501. When lens 502 is not offset from optical axis AX, illumination spot 333 on substrate W coincides with optical axis AX. When variable focal length lens 502 is offset from optical axis AX, illumination spot 333 on substrate W also becomes offset from optical axis AX. An offset from optical axis AX of variable focal length lens 502 leads radiation beam 306 to reflect off spot mirror 320 at a different angle, which in turn leads to an illumination spot 333 that is offset from optical axis AX.

For optical module non-mechanical beam scanning of the alignment mark, the design shown in FIG. 5E ensures that beam steering will still fall within spot mirror 320. Current spot sizes and spot mirror sizes ensure that 0^{th} order blocking is maintained. Even though the beam 306 is offset from the optical axis AX when incident on substrate W, the Oth order of the diffracted radiation beam 335 is still blocked by spot mirror 320. As a result, dark field measurements are still possible, since the Oth order beam has been blocked. Further, both regular and angled raster scans can be achieved without employing mechanical elements. Additionally, there is a combined bi-directional angled scan. In turn, lateral scan offset is compensated.

In other embodiments, beam steering can be used in conjunction with a high bandwidth detector and a constant high velocity substrate table WT for more marks, to account for doppler shifts of different marks. Furthermore, additional coherent Illumination spot at substrate W can be generated and provide beam steering over the original beam spot. Aligned position as a function of beam steering angle can be achieved. Alternatively, direct beams can be put onto the detector directly.

### Variable Focus Alignment System

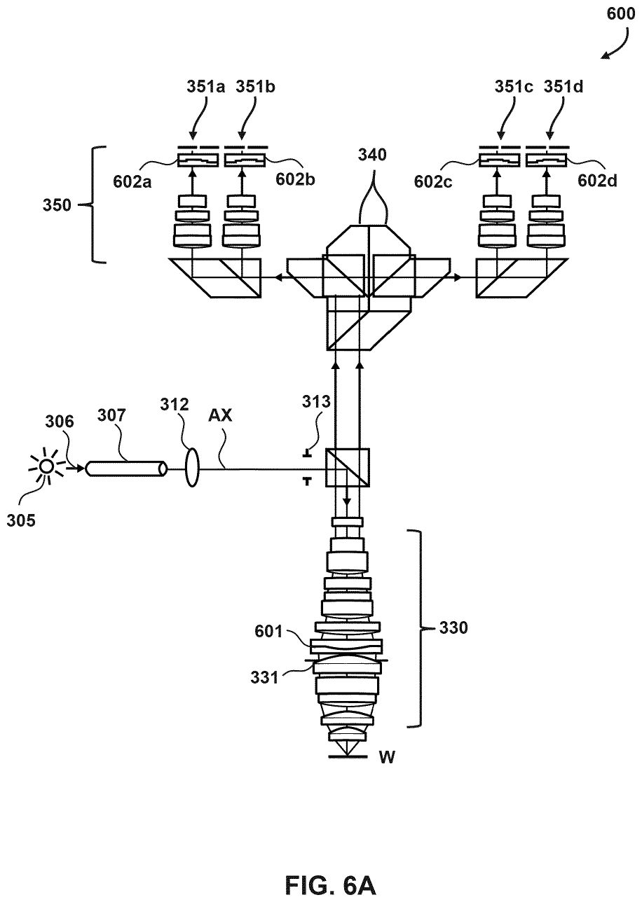

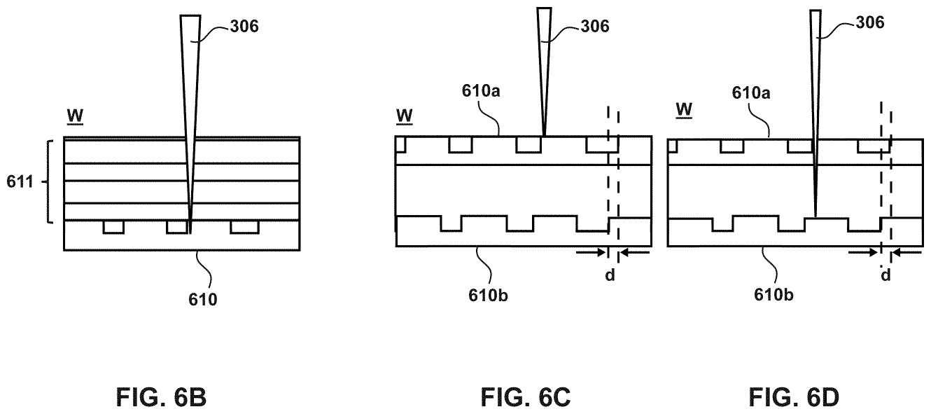

FIG. 6A illustrates a schematic of a variable focus alignment system 600. Other than removing input fiber assembly (IFA) 311 and adding first variable focal length lens 601 in objective 330 and second variable focal length lenses 602a-602d in output channels 351a-351d, respectively, variable focus alignment system 600 is the same as the alignment system 300 in FIG. 3.

According to an embodiment, first variable focal length lens 601 is positioned in objective 330. Second variable focal length lenses 602a, 602b, 602c, and 602d are positioned in output channels 351a, 351b, 351c, and 351d, respectively. As a result, each output channel radiation beam will travel through a pair of variable focal length lenses, which are first variable focal length lens 601 and the output channel's second variable focal length lens, one of 602a-602d. These variable focal length lenses are positioned in the collection path of the sensor. Therefore, when there are “N” output channels, then there are “N+1” variable focal length lenses in the alignment system. In the example of FIG. 6A, there are 4 (N) output channels and 5 (N+1) variable focal length lenses. There is first variable focal length lens 601 in objective 330 and four second variable focal length lenses 602a-602d in output channels 351a-351d, for a total of 5 variable focal length lenses.

By having first variable focal length lens 601 in objective 330 and second variable focal length lenses 602a-602d in output channels 351a-351d, respectively, the focus of the radiation beam at substrate W can be changed. Varying the focus allows for measurement at alignment marks positioned at different z levels. As a result, the alignment system 600 has the capability to align over warped substrates or thick resist layers and perform overlay. Further, variable focus for through stack measurement allows for thick stack measurements and diffraction-based overlay within the alignment sensor.

For example, FIG. 6B illustrates a schematic of a thick resist substrate W in the variable focus alignment system 600 (FIG. 6A). The substrate W comprises alignment mark 610 positioned below resist layers 611. Despite the thickness of the multiple layers 611 of photoresist, the underlying alignment mark 610 layer remains in focus. By applying voltage to the variable focal length lenses 601 and 602a-d (shown in FIG. 6A), the focal length of the radiation beam 306 can be changed such that the radiation beam 306 is focused at the alignment mark 610 level. In some embodiments, thick 3DNAND stacks having thick resists and warped wafers can be aligned using variable focus alignment system 600.

FIGS. 6C-6D illustrate a schematic of measuring overlay (e.g., an amount of offset “d”) for alignment marks 610a and 610b in the variable focus alignment system. In FIG. 6C, a top alignment mark 610a (a grating) can be measured by focusing the radiation beam 306 at the surface of the alignment mark 610a. In FIG. 6D, a bottom alignment mark 610b (a grating) can be measured by focusing the radiation beam 306 at the surface of the alignment mark 610b. As a result, an offset “d” between the alignment mark gratings can be determined. For example, variable focus can be applied in Z-Star systems with diffraction gratings at different z levels.

Variable focus alignment system 600 (FIG. 6A) is capable of maintaining the same mark pitch range. The numerical aperture pitch is between 0.118 and 0.7. Variable focus accounts for typical thick stacks on the order of millimeters. Further, the use of variable focus length lenses 401 and 402 at the IFA, such as in FIG. 4C, can be used with variable focus to maintain the spot size at different foci. Overlay capability in the variable focus alignment system 600 is achieved by using multi z level alignment signals. Further, variable focus can be used in alignment system 600 to provide adjustable working distances at commercially proven aperture sizes. Variable focus can also be deployed in YieldStar for overlay metrology.

### Spot Shift and Higher Order Rejection Alignment System

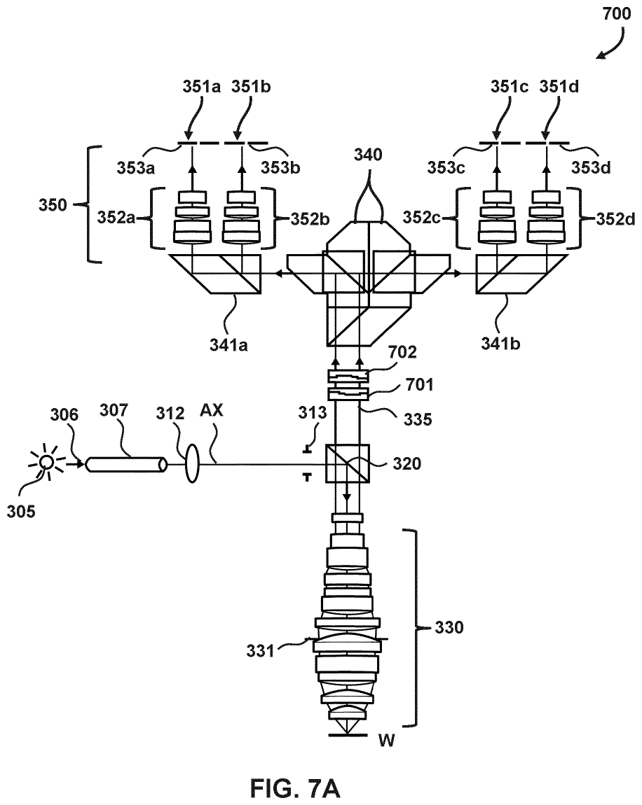

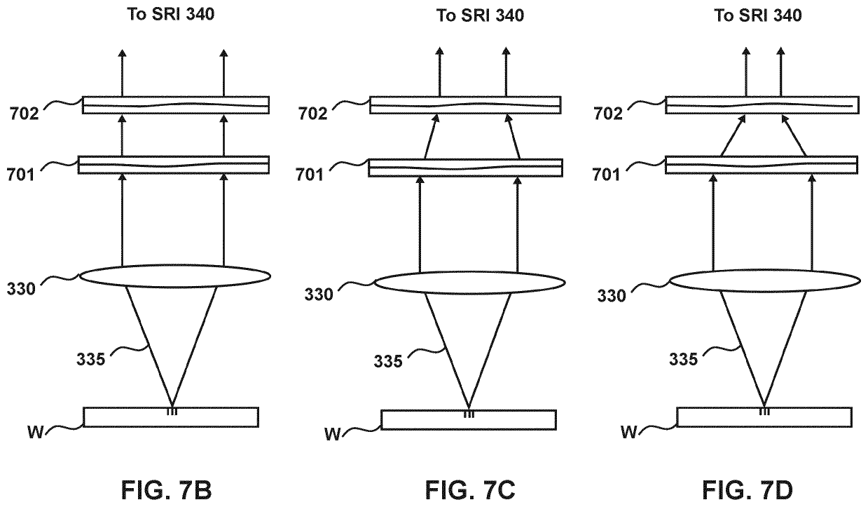

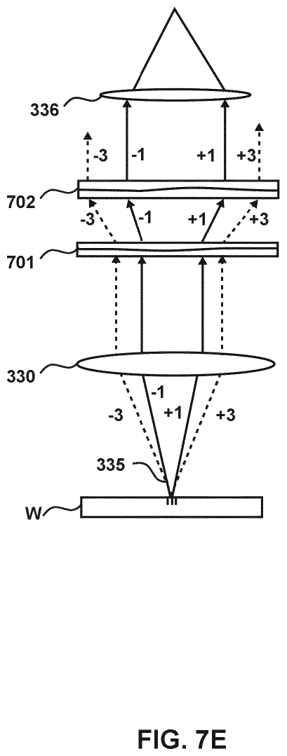

FIG. 7A illustrates a schematic of an alignment system 700 for spot shift and higher order rejection. Other than removing input fiber assembly (IFA) 311 and adding first variable focal length lens 701 and second variable focal length lens 702 in a pupil plane, alignment system 700 is the same as the alignment system 300 in FIG. 3.

According to an embodiment, first variable focal length lens 701 and second variable focal length lens 702 (each being similar to and/or the same as lens 420 described above) are positioned in the pupil plane downstream of objective 330 and upstream of self-referencing interferometers 340. Positioning variable focal length lenses 701 and 702 at the pupil plane provides for spot shift calibration and higher order rejection. For example, by applying differing voltages to the variable focal length lenses 701 and 702, calibrating a spot shift of the diffracted radiation beam 335 can be achieved.

FIGS. 7B-7D illustrate a schematic for calibrating a spot shift using variable focal length lenses 701 and 702. FIG. 7B illustrates a diffracted radiation beam 335 spot shift for variable focal length lenses 701 and 702 having a nominal voltage. The diffracted radiation beam 335 reflects off an alignment mark on substrate W. The diffracted radiation beam 335 expands until it reaches the objective 330, when the light rays change to parallel. With a nominal voltage applied to each of the variable focal length lenses 701 and 702, there is no curvature in the water-oil interface 406 (see FIGS. 4A and 4B). As a result, the parallel diffracted radiation beam 335 remains the same upon exiting each lens 701 and 702. Thereafter, the beam 335 travels to the self-referencing interferometers 340.

FIG. 7C illustrates a spot shift for the diffracted radiation beam 335 with the lenses 701 and 702 having a medium voltage. The diffracted radiation beam 335 reflects off an alignment mark on substrate W. The diffracted radiation beam 335 expands until it reaches the objective 330, when the light rays change to parallel. With a medium voltage applied, a curvature is formed at the interface 406 (see FIGS. 4A and 4B). As a result, the diffracted radiation beam 335 has shifted to a smaller spot size upon exiting second lens 702. Thereafter, the beam 335 is incident on the self-referencing interferometers 340.

FIG. 7D illustrates a spot shift for the diffracted radiation beam 335 with the lenses 701 and 702 having a high voltage. FIG. 7D is similar to FIG. 7C except for the degree of voltage applied. Since a higher voltage is used, the curvature of the interface 406 (see FIGS. 4A and 4B) is sharper. As a result, the diffracted radiation beam 335 has shifted to an even smaller spot size upon exiting second lens 702.

By positioning the afocal lens system (lenses 701 and 702) in the pupil plane (see the location of 701 and 702 in FIG. 7A), pupil metrology compensation can be performed. Pupil metrology can be used to account for product crosstalk. Product crosstalk is the signal that leaks to the detection system from the surroundings structures of the target mark. Crosstalk occurs when the spot size is varied (such as in the alignment system 400 of FIG. 4C) and yet the aperture field stop (such as aperture stop 313) and the illumination field stop remain the same. If the alignment mark is not underfilled, then signal leakage from neighboring structures to the alignment diffraction grating on the substrate W will be captured. In other words, increasing the spot size will irradiate not only the alignment mark but also surrounding structures adjacent to the alignment grating. Using spot shift calibration in pupil metrology, however, product crosstalk can be alleviated.

Further, spot shift can be used to compensate for Delta R effects. Delta R effects are the reweighing of the diffraction beam NA due to the product wafer stack. Since there is no explicit pupil metrology which can help measure the shift of the spot in the pupil, the Delta R effects will be undetectable. Delta R effects may occur when the diffracted radiation beam 335 from the substrate W shifts due to the stack on the alignment mark. Delta R effects can be compensated for by calibrating for change in the wavefront sample due to stack variations. The calibration can be performed by generating the return signal as a function of the spot shift. This curve can be compared to the calibration curve as measured for the same target mark pitch on a fiducial. The spot shift is facilitated by the tunable system. Consequently, pupil metrology allows for stack measurements and facilitates smaller marks (e.g., as described above related to FIG. 7B-7D).

Second, inserting variable focal length lenses 701 and 702 into the pupil plane (see the location of 701 and 702 in FIG. 7A) yields higher order rejection. FIG. 7E illustrates applying voltage to variable focal length lenses 701 and 702 in the pupil plane to reject higher diffraction orders. The diffracted radiation beam 335 reflects off the surface of the substrate W and is split into diffraction beam spots. FIG. 7E illustrates the 1^{st} and 3^{rd} order diffraction beam spots. The objective 330 receives the beam spots and passes the beam spots to the variable focal length lenses 701 and 702. The application of voltage to the lenses 701 and 702 creates a curvature in the interface 406 (see FIGS. 4A and 4B) that pushes the beam spots radially outward away from the optical axis (not shown). Upon exiting the second lens 702, the 3^{rd} order diffraction beams are so radially outward that they are outside of the clear aperture of lens 336. As a result, the +3 and −3 diffraction order beam spots are filtered out and do not pass through the lens 336. On the other hand, the +1 and −1 diffraction order beams, despite being pushed outwards, are still within the aperture of the lens 336 and thereby pass through.

Tunable beam shifting as a function of mark pitch allows rejection of higher orders (e.g., Nth high orders could be rejected (N>1)) within the optical module. In the case of FIG. 7E, it is desired to remove the 3^{rd} order diffraction beams; otherwise, they would pollute the signal. Therefore, higher order diffraction orders of the mark pitch can be filtered out. Higher diffraction order contributions from the mark cannot be separated using a single pixel detector (e.g., I+total=I+1+I+2+I+3 . . . ). In prior systems, only the total de signal, I+total and I−total, can be measured. Algorithms to correct for the aligned position errors demand knowledge of the pair of diffraction orders, such as +1 and −1, +2 and −2, etc. Removing higher order signals and calculating alignment position based solely on the detected order results in higher accuracy and less noise to the o/p position.

Alignment system 700 (FIG. 7A) is a non-mechatronic alternative to reject the unwanted orders. Instead of using mechatronics to remove higher diffraction orders, variable focal length lenses 701 and 702 can be applied. As a result, alignment system 700 can be improved by using variable focal length lenses 701 and 702 rather than mechatronic elements.

### Multiple Alignment System Embodiments Usable Together

One or more of the components and/or systems shown in FIGS. 4A-7E can be usable together in the alignment system 300 of FIG. 3. In other words, for example, alignment system 300 can be adjusted to include illumination systems 410 and 510 of FIGS. 4A and 5A, respectively, first variable focal length lens 601 of FIG. 6A in objective 330 and second variable focal length lenses 602a-602d of FIG. 6A in output channels 351a-351d, respectively, and variable focal length lenses 701 and 702 of FIG. 7A in the pupil plane. This results in three sets of variable focal length lenses positioned in alignment system 300. In this embodiment, variable focal length lenses in alignment system 300 can be either positioned on optical axis AX like 401 and 402 in FIG. 4C or one can be positioned offset from optical axis AX like 502 in FIG. 5A.

Further, two embodiments can be used together. For example, illumination system 410 of FIG. 4C and variable focal length lenses 601 and 602a-602d of FIG. 6A can be used together in alignment system 300 of FIG. 3. Alternatively, illumination system 510 of FIG. 5A and variable focal length lenses 701 and 702 of FIG. 7A are usable together. Needless to say, any combination of embodiments can be used together in alignment system 300. The benefits and advantages described above would be present in this embodiment.

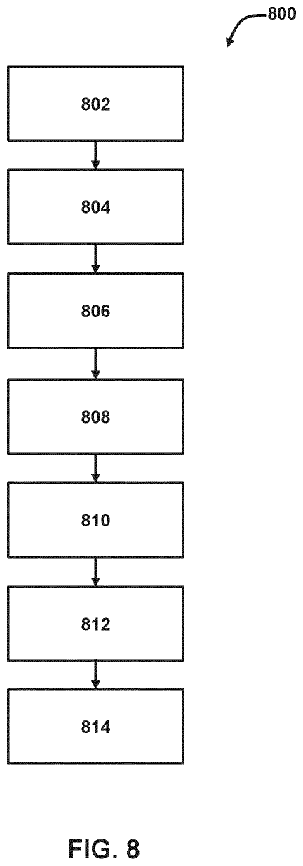

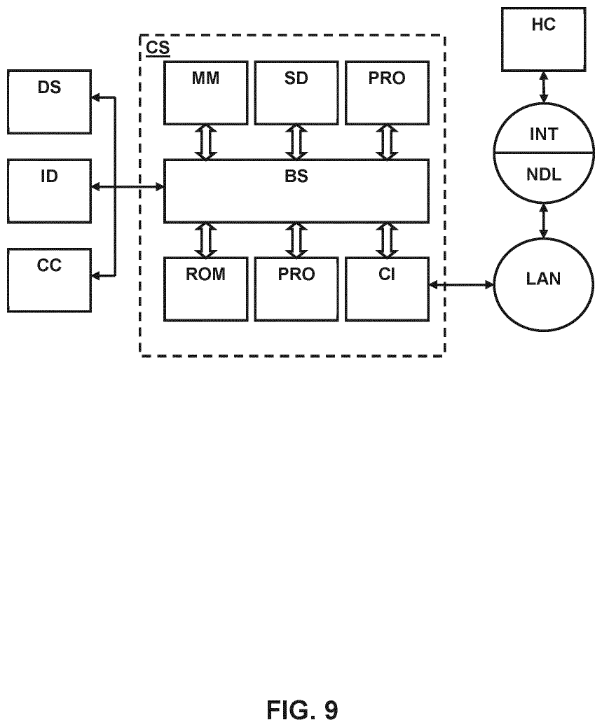

FIG. 8 illustrates an alignment method 800. In some embodiments, method 800 is performed as part of an alignment sensing operation in a semiconductor device manufacturing process, for example. In some embodiments, one or more operations of method 800 may be implemented in or by the systems described herein, including a computer system (e.g., as illustrated in FIG. 9 and described below), and/or in or by other systems, for example. In some embodiments, method 800 comprises generating (802) a radiation beam output with an illumination source; receiving (804), with a first set of variable focal length lenses, the radiation beam; controlling (806) the first set of variable focal length lenses to vary an illumination spot size at a wafer; positioning (808) a second set of variable focal length lenses, one lens of the second set of variable focal length lenses positioned in an output channel and another lens of the second set of variable focal length lenses positioned in an objective system; (810) controlling the second set of variable focal length lenses to vary a height of focus of an output from the objective system; positioning (812) a third set of variable focal length lenses in a pupil plane downstream of the objective system; controlling (814) the third set of variable focal length lenses to vary at least one of spot shift and higher order diffraction orders, and/or other operations.

The operations of method 800 are intended to be illustrative. In some embodiments, method 800 may be accomplished with one or more additional operations not described, and/or without one or more of the operations discussed. For example, in some embodiments, method 800 may include an additional operation comprising determining an adjustment for a semiconductor device manufacturing process. In some embodiments, method 800 includes determining one or more semiconductor device manufacturing process parameters. The one or more semiconductor device manufacturing process parameters may be determined based on an alignment value indicated by a metrology signal, and/or other similar systems, and/or other information. The one or more parameters may include a parameter of the radiation (the radiation used for metrology), an overlay value, an alignment value, a metrology inspection location on a layer of a semiconductor device structure, a radiation beam trajectory across a target, and/or other parameters. In some embodiments, process parameters can be interpreted broadly to include a stage position, a mask design, a metrology target design, a semiconductor device design, an intensity of the radiation (used for exposing resist, etc.), an incident angle of the radiation (used for exposing resist, etc.), a wavelength of the radiation (used for exposing resist, etc.), a pupil size and/or shape, a resist material, and/or other parameters.

In some embodiments, method 800 includes determining a process adjustment based on the one or more determined semiconductor device manufacturing process parameters, adjusting a semiconductor device manufacturing apparatus based on the determined adjustment, and/or other operations. For example, if a determined alignment measurement is not within process tolerances, the out of tolerance measurement may be caused by one or more manufacturing processes whose process parameters have drifted and/or otherwise changed so that the process is no longer producing acceptable devices (e.g., measurements may breach a threshold for acceptability). One or more new or adjusted process parameters may be determined based on the measurement determination. The new or adjusted process parameters may be configured to cause a manufacturing process to again produce acceptable devices.

For example, a new or adjusted process parameter may cause a previously unacceptable measurement value to be adjusted back into an acceptable range. The new or adjusted process parameters may be compared to existing parameters for a given process. If there is a difference, that difference may be used to determine an adjustment for an apparatus that is used to produce the devices (e.g., parameter “x” should be increased/decreased/changed so that it matches the new or adjusted version of parameter “x” determined as part of method 800), for example. In some embodiments, method 800 may include electronically adjusting an apparatus (e.g., based on the determined process parameters). Electronically adjusting an apparatus may include sending an electronic signal, and/or other communications to the apparatus, for example, which causes a change in the apparatus. The electronic adjustment may include changing a setting on the apparatus, for example, and/or other adjustments.

Additionally, the order in which the operations of method 800 are illustrated in FIG. 8 and described herein is not intended to be limiting.

In some embodiments, one or more portions of method 800 may be implemented in and/or controlled by one or more processing devices (e.g., a digital processor, an analog processor, a digital circuit designed to process information, an analog circuit designed to process information, a state machine, and/or other mechanisms for electronically processing information). The one or more processing devices may include one or more devices executing some or all of the operations of method 800 in response to instructions stored electronically on an electronic storage medium. The one or more processing devices may include one or more devices configured through hardware, firmware, and/or software to be specifically designed for execution of one or more of the operations of method 800 (e.g., see discussion related to FIG. 9 below).

FIG. 9 is a diagram of an example computer system CS that may be used for one or more of the operations described herein. Computer system CS includes a bus BS or other communication mechanism for communicating information, and a processor PRO (or multiple processors similar to and/or the same as processor PRO shown in FIG. 3) coupled with bus BS for processing information. Computer system CS also includes a main memory MM, such as a random access memory (RAM) or other dynamic storage device, coupled to bus BS for storing information and instructions to be executed by processor PRO. Main memory MM also may be used for storing temporary variables or other intermediate information during execution of instructions by processor PRO. Computer system CS further includes a read only memory (ROM) ROM or other static storage device coupled to bus BS for storing static information and instructions for processor PRO. A storage device SD, such as a magnetic disk or optical disk, is provided and coupled to bus BS for storing information and instructions.

Computer system CS may be coupled via bus BS to a display DS, such as a flat panel or touch panel display or a cathode ray tube (CRT) for displaying information to a computer user. An input device ID, including alphanumeric and other keys, is coupled to bus BS for communicating information and command selections to processor PRO. Another type of user input device is cursor control CC, such as a mouse, a trackball, or cursor direction keys for communicating direction information and command selections to processor PRO and for controlling cursor movement on display DS. This input device typically has two degrees of freedom in two axes, a first axis (e.g., x) and a second axis (e.g., y), that allows the device to specify positions in a plane. A touch panel (screen) display may also be used as an input device.

In some embodiments, all or some of one or more operations described herein may be performed by computer system CS in response to processor PRO executing one or more sequences of one or more instructions contained in main memory MM. Such instructions may be read into main memory MM from another computer-readable medium, such as storage device SD. Execution of the sequences of instructions included in main memory MM causes processor PRO to perform the process steps (operations) described herein. One or more processors in a multi-processing arrangement may also be employed to execute the sequences of instructions contained in main memory MM. In some embodiments, hard-wired circuitry may be used in place of or in combination with software instructions. Thus, the description herein is not limited to any specific combination of hardware circuitry and software.

The term “computer-readable medium” or “machine-readable medium” as used herein refers to any medium that participates in providing instructions to processor PRO for execution. Such a medium may take many forms, including but not limited to, non-volatile media, volatile media, and transmission media. Non-volatile media include, for example, optical or magnetic disks, such as storage device SD. Volatile media include dynamic memory, such as main memory MM. Transmission media include coaxial cables, copper wire and fiber optics, including the wires that comprise bus BS. Transmission media can also take the form of acoustic or light waves, such as those generated during radio frequency (RF) and infrared (IR) data communications. Computer-readable media can be non-transitory, for example, a floppy disk, a flexible disk, hard disk, magnetic tape, any other magnetic medium, a CD-ROM, DVD, any other optical medium, punch cards, paper tape, any other physical medium with patterns of holes, a RAM, a PROM, and EPROM, a FLASH-EPROM, any other memory chip or cartridge. Non-transitory computer readable media can have instructions recorded thereon. The instructions, when executed by a computer, can implement any of the operations described herein. Transitory computer-readable media can include a carrier wave or other propagating electromagnetic signal, for example.

Various forms of computer readable media may be involved in carrying one or more sequences of one or more instructions to processor PRO for execution. For example, the instructions may initially be borne on a magnetic disk of a remote computer. The remote computer can load the instructions into its dynamic memory and send the instructions over a telephone line using a modem. A modem local to computer system CS can receive the data on the telephone line and use an infrared transmitter to convert the data to an infrared signal. An infrared detector coupled to bus BS can receive the data carried in the infrared signal and place the data on bus BS. Bus BS carries the data to main memory MM, from which processor PRO retrieves and executes the instructions. The instructions received by main memory MM may optionally be stored on storage device SD either before or after execution by processor PRO.

Computer system CS may also include a communication interface CI coupled to bus BS. Communication interface CI provides a two-way data communication coupling to a network link NDL that is connected to a local network LAN. For example, communication interface CI may be an integrated services digital network (ISDN) card or a modem to provide a data communication connection to a corresponding type of telephone line. As another example, communication interface CI may be a local area network (LAN) card to provide a data communication connection to a compatible LAN. Wireless links may also be implemented. In any such implementation, communication interface CI sends and receives electrical, electromagnetic or optical signals that carry digital data streams representing various types of information.

Network link NDL typically provides data communication through one or more networks to other data devices. For example, network link NDL may provide a connection through local network LAN to a host computer HC. This can include data communication services provided through the worldwide packet data communication network, now commonly referred to as the “Internet” INT. Local network LAN (Internet) may use electrical, electromagnetic or optical signals that carry digital data streams. The signals through the various networks and the signals on network data link NDL and through communication interface CI, which carry the digital data to and from computer system CS, are exemplary forms of carrier waves transporting the information.

Computer system CS can send messages and receive data, including program code, through the network(s), network data link NDL, and communication interface CI. In the Internet example, host computer HC might transmit a requested code for an application program through Internet INT, network data link NDL, local network LAN, and communication interface CI. One such downloaded application may provide all or part of a method described herein, for example. The received code may be executed by processor PRO as it is received, and/or stored in storage device SD, or other non-volatile storage for later execution. In this manner, computer system CS may obtain application code in the form of a carrier wave.

This specification discloses one or more embodiments that incorporate the features of this invention. The disclosed embodiment(s) merely exemplify the invention. The scope of the invention is not limited to the disclosed embodiment(s). The invention is defined by the claims appended hereto.

The embodiment(s) described, and references in the specification to “one embodiment,” “an embodiment,” “an example embodiment,” etc., indicate that the embodiment(s) described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is understood that it is within the knowledge of one skilled in the art to affect such feature, structure, or characteristic in connection with other embodiments whether or not explicitly described.

Although specific reference may be made in this text to the use of lithographic apparatus in the manufacture of ICs, it should be understood that the lithographic apparatus described herein may have other applications, such as the manufacture of integrated optical systems, guidance and detection patterns for magnetic domain memories, flat-panel displays, liquid-crystal displays (LCDs), thin-film magnetic heads, etc. The skilled artisan will appreciate that, in the context of such alternative applications, any use of the terms “wafer” or “die” herein may be considered as synonymous with the more general terms “substrate” or “target portion”, respectively. The substrate referred to herein may be processed, before or after exposure, in for example a track (a tool that typically applies a layer of resist to a substrate and develops the exposed resist), a metrology tool and/or an inspection tool. Where applicable, the disclosure herein may be applied to such and other substrate processing tools. Further, the substrate may be processed more than once, for example in order to create a multi-layer IC, so that the term substrate used herein may also refer to a substrate that already contains multiple processed layers.

Although specific reference may have been made above to the use of embodiments of the invention in the context of optical lithography, it will be appreciated that the invention may be used in other applications, for example imprint lithography, and where the context allows, is not limited to optical lithography. In imprint lithography a topography in a patterning device defines the pattern created on a substrate. The topography of the patterning device may be pressed into a layer of resist supplied to the substrate whereupon the resist is cured by applying electromagnetic radiation, heat, pressure or a combination thereof. The patterning device is moved out of the resist leaving a pattern in it after the resist is cured.

It is to be understood that the phraseology or terminology herein is for the purpose of description and not of limitation, such that the terminology or phraseology of the present specification is to be interpreted by those skilled in relevant art(s) in light of the teachings herein.

In the embodiments described herein, the terms “lens” and “lens element,” where the context allows, can refer to any one or combination of various types of optical components, including refractive, reflective, magnetic, electromagnetic, and electrostatic optical components.

Further, the terms “radiation” and “beam” used herein encompass all types of electromagnetic radiation, including ultraviolet (UV) radiation (for example, having a wavelength λ of 365, 248, 193, 157 or 126 nm), extreme ultraviolet (EUV or soft X-ray) radiation (for example, having a wavelength in the range of 5-20 nm such as, for example, 13.5 nm), or hard X-ray working at less than 5 nm, as well as particle beams, such as ion beams or electron beams. Generally, radiation having wavelengths between about 400 to about 700 nm is considered visible radiation; radiation having wavelengths between about 780-3000 nm (or larger) is considered IR radiation. UV refers to radiation with wavelengths of approximately 100-400 nm. Within lithography, the term “UV” also applies to the wavelengths that can be produced by a mercury discharge lamp: G-line 436 nm; H-line 405 nm; and/or, I-line 365 nm. Vacuum UV, or VUV (i.e., UV absorbed by gas), refers to radiation having a wavelength of approximately 100-200 nm. Deep UV (DUV) generally refers to radiation having wavelengths ranging from 126 nm to 428 nm, and in an embodiment, an excimer laser can generate DUV radiation used within a lithographic apparatus. It should be appreciated that radiation having a wavelength in the range of, for example, 5-20 nm relates to radiation with a certain wavelength band, of which at least part is in the range of 5-20 nm.

The term “substrate” as used herein generally describes a material onto which subsequent material layers are added. In embodiments, the substrate itself may be patterned and materials added on top of it may also be patterned, or may remain without patterning.

The term “in substantial contact” as used herein generally describes elements or structures that are in physical contact with each other with only a slight separation from each other which typically results from misalignment tolerances. It should be understood that relative spatial descriptions between one or more particular features, structures, or characteristics (e.g., “vertically aligned,” “substantial contact,” etc.) used herein are for purposes of illustration only, and that practical implementations of the structures described herein may include misalignment tolerances without departing from the spirit and scope of the present disclosure.

The term “optically coupled” as used herein generally refers to one coupled element being configured to impart light to another coupled element directly or indirectly.

The term “optical material” as used herein generally refers to a material that allows light or optical energy to propagate therein or therethrough.

While specific embodiments of the invention have been described above, it will be appreciated that the invention may be practiced otherwise than as described. The description is not intended to limit the invention.

It is to be appreciated that the Detailed Description section, and not the Summary and Abstract sections, is intended to be used to interpret the claims. The Summary and Abstract sections may set forth one or more but not all exemplary embodiments of the present invention as contemplated by the inventor(s), and thus, are not intended to limit the present invention and the appended claims in any way.

The present invention has been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

Various embodiments of the present systems and methods are disclosed in the subsequent list of numbered clauses. In the following, further features, characteristics, and exemplary technical solutions of the present disclosure will be described in terms of clauses that may be optionally claimed in any combination:
1. A wafer alignment measurement system comprising: an illumination source; a radiation beam output from the illumination source; a first set of variable focal length lenses configured to receive the radiation beam, wherein the first set of variable focal length lenses are controllable to control an illumination spot size at a wafer; a second set of variable focal length lenses, one positioned in an output channel and another positioned in an objective system, wherein the second set of variable focal length lenses are controllable to control a height of focus of an output from the objective system; and a third set of variable focal length lenses positioned in a pupil plane downstream of the objective system, wherein the third set of variable focal length lenses are controllable to control at least one of spot shift and higher order diffraction orders.
2. The wafer alignment measurement system of clause 1, wherein the first set of variable focal length lenses are positioned in an illumination system. 3. The wafer alignment measurement system of any of the previous clauses, wherein one first
variable focal length lens is offset from an optical axis of the radiation beam.
4. The wafer alignment measurement system of any of the previous clauses, wherein there are “N” output channels and “N+1” second variable focal length lenses, wherein there is one second variable focal length lens in each output channel and one second variable focal length lens in the objective system.
5. The wafer alignment measurement system of any of the previous clauses, wherein the third set of variable focal length lenses is positioned in a pupil plane.
6. The wafer alignment measurement system of any of the previous clauses, wherein the first, second, and third sets of variable focal length lenses are controllable by applying voltage to the first, second, and third sets of variable focal length lenses.
7. A wafer alignment measurement system comprising: an illumination source; a radiation beam output from the illumination source; and at least two variable focal length lenses configured to receive the radiation beam, wherein the variable focal length lenses are controllable to control an illumination spot size at a wafer.
8. The wafer alignment measurement system of any of the previous clauses, wherein the variable focal length lenses are positioned in an illumination system.
9. The wafer alignment measurement system of any of the previous clauses, wherein the variable focal length lenses are positioned in the illumination system between an illumination relay lens and an aperture stop.
10. The wafer alignment measurement system of any of the previous clauses, wherein the variable focal length lenses are controllable by applying voltage to the variable focal length lenses.
11. The wafer alignment measurement system of any of the previous clauses, wherein one variable focal length lens is offset from an optical axis of the radiation beam.
12. A wafer alignment measurement system comprising: an illumination source; and at least two variable focal length lenses, one positioned in an output channel and another positioned in an objective system, wherein the variable focal length lenses are controllable to control a height of focus of an output from the objective system.
13. The wafer alignment measurement system of any of the previous clauses, wherein an output of the illumination source is a radiation beam that reflects off a wafer.
14. The wafer alignment measurement system of any of the previous clauses, wherein the radiation beam passes through the variable focal length lenses after reflecting off the wafer.
15. The wafer alignment measurement system of any of the previous clauses, wherein there are “N” output channels and “N+1” variable focal length lenses, wherein there is one variable focal length lens in each output channel and one variable focal length lens in the objective system.
16. The wafer alignment measurement system of any of the previous clauses, wherein the variable focal length lenses are controllable by applying voltage to the variable focal length lenses.
17. A wafer alignment measurement system comprising: an illumination source; a radiation beam output from the illumination source that travels to an objective system; and at least two variable focal length lenses positioned in a pupil plane downstream of the objective system, wherein the variable focal length lenses are controllable to control at least one of spot shift and higher order diffraction orders.
18. The wafer alignment measurement system of any of the previous clauses, wherein the variable focal length lenses are positioned in a pupil plane.
19. The wafer alignment measurement system of any of the previous clauses, wherein the variable focal length lenses are positioned in the pupil plane between the objective system and a self-referencing interferometer.
20. The wafer alignment measurement system of any of the previous clauses, wherein the variable focal length lenses compensate for spot shift.
21. The wafer alignment measurement system of any of the previous clauses, wherein the variable focal length lenses compensate for higher order diffraction orders.
22. The wafer alignment measurement system of any of the previous clauses, wherein the variable focal length lenses are controllable by applying voltage to the variable focal length lenses.
23. A wafer alignment measurement method, the method comprising: generating a radiation beam output with an illumination source; receiving, with a first set of variable focal length lenses, the radiation beam; controlling the first set of variable focal length lenses to vary an illumination spot size at a wafer; positioning a second set of variable focal length lenses, one lens of the second set of variable focal length lenses positioned in an output channel and another lens of the second set of variable focal length lenses positioned in an objective system; controlling the second set of variable focal length lenses to vary a height of focus of an output from the objective system; positioning a third set of variable focal length lenses in a pupil plane downstream of the objective system; and controlling the third set of variable focal length lenses to vary at least one of spot shift and higher order diffraction orders.
24. The wafer alignment measurement method of clause 23, wherein the first set of variable focal length lenses are positioned in an illumination system.
25. The wafer alignment measurement method of any of the previous clauses, wherein one first variable focal length lens is offset from an optical axis of the radiation beam.
26. The wafer alignment measurement method of any of the previous clauses, wherein there are “N” output channels and “N+1” second variable focal length lenses, wherein there is one second variable focal length lens in each output channel and one second variable focal length lens in the objective system.
27. The wafer alignment measurement method of any of the previous clauses, wherein the third set of variable focal length lenses is positioned in a pupil plane.
28. The wafer alignment measurement method of any of the previous clauses, wherein the first, second, and third sets of variable focal length lenses are controllable by applying voltage to the first, second, and third sets of variable focal length lenses.
29. A wafer alignment measurement method comprising: generating a radiation beam output from an illumination source; receiving, with at least two variable focal length lenses, the radiation beam; and controlling the variable focal length lenses to vary an illumination spot size at a wafer.
30. The wafer alignment measurement method of any of the previous clauses, wherein the variable focal length lenses are positioned in an illumination system.
31. The wafer alignment measurement method of any of the previous clauses, wherein the variable focal length lenses are positioned in the illumination system between an illumination relay lens and an aperture stop.
32. The wafer alignment measurement method of any of the previous clauses, wherein the variable focal length lenses are controllable by applying voltage to the variable focal length lenses.
33. The wafer alignment measurement method of any of the previous clauses, wherein one variable focal length lens is offset from an optical axis of the radiation beam.
34. A wafer alignment measurement method, the method comprising: an illumination source; and at least two variable focal length lenses, one positioned in an output channel and another positioned in an objective system, wherein the variable focal length lenses are controllable to control a height of focus of an output from the objective system.
35. The wafer alignment measurement method of any of the previous clauses, wherein an output of the illumination source is a radiation beam that reflects off a wafer.
36. The wafer alignment measurement method of any of the previous clauses, wherein the radiation beam passes through the variable focal length lenses after reflecting off the wafer.
37. The wafer alignment measurement method of any of the previous clauses, wherein there are “N” output channels and “N+1” variable focal length lenses, wherein there is one variable focal length lens in each output channel and one variable focal length lens in the objective system.
38. The wafer alignment measurement method of any of the previous clauses, wherein the variable focal length lenses are controllable by applying voltage to the variable focal length lenses.
39. A wafer alignment measurement method, the method comprising: generating a radiation beam output from an illumination source that travels to an objective system; positioning at least two variable focal length lenses in a pupil plane downstream of the objective system; and controlling the variable focal length lenses to vary at least one of spot shift and higher order diffraction orders.
40. The wafer alignment measurement method of any of the previous clauses, wherein the variable focal length lenses are positioned in a pupil plane.
41. The wafer alignment measurement method of any of the previous clauses, wherein the variable focal length lenses are positioned in the pupil plane between the objective system and a self-referencing interferometer.
42. The wafer alignment measurement method of any of the previous clauses, wherein the variable focal length lenses compensate for spot shift.
43. The wafer alignment measurement method of any of the previous clauses, wherein the variable focal length lenses compensate for higher order diffraction orders.
44. The wafer alignment measurement method of any of the previous clauses, wherein the variable focal length lenses are controllable by applying voltage to the variable focal length lenses.

The foregoing description of the specific embodiments will so fully reveal the general nature of the invention that others can, by applying knowledge within the skill of the art, readily modify and/or adapt for various applications such specific embodiments, without undue experimentation, without departing from the general concept of the present invention. Therefore, such adaptations and modifications are intended to be within the meaning and range of equivalents of the disclosed embodiments, based on the teaching and guidance presented herein.

The breadth and scope of the present invention should not be limited by any of the above-described exemplary embodiments but should be defined only in accordance with the following claims and their equivalents.

1. A wafer alignment measurement system comprising:
an illumination source; and
at least two variable focal length lenses, one positioned in an output channel and another positioned in an objective system, wherein the variable focal length lenses are controllable to control a height of focus of an output from the objective system.

2. The wafer alignment measurement system of claim 1, wherein an output of the illumination source is a radiation beam that reflects off a wafer.

3. The wafer alignment measurement system of claim 2, wherein the radiation beam passes through the variable focal length lenses after reflecting off the wafer.

4. The wafer alignment measurement system of claim 3, wherein there are “N” output channels and “N+1” variable focal length lenses, wherein there is one variable focal length lens in each output channel and one variable focal length lens in the objective system.

5. The wafer alignment measurement system of claim 3, wherein the variable focal length lenses are controllable by applying voltage to the variable focal length lenses.

6. A wafer alignment measurement system comprising:
an illumination source;
a radiation beam output from the illumination source that travels to an objective system; and
at least two variable focal length lenses positioned in a pupil plane downstream of the objective system, wherein the variable focal length lenses are controllable to control at least one of spot shift and higher order diffraction orders.

7. The wafer alignment measurement system of claim 6, wherein the variable focal length lenses are positioned in a pupil plane.

8. The wafer alignment measurement system of claim 6, wherein the variable focal length lenses are positioned in the pupil plane between the objective system and a self-referencing interferometer.

9. The wafer alignment measurement system of claim 6, wherein the variable focal length lenses compensate for spot shift.

10. The wafer alignment measurement system of claim 6, wherein the variable focal length lenses compensate for higher order diffraction orders.

11. The wafer alignment measurement system of claim 6, wherein the variable focal length lenses are controllable by applying voltage to the variable focal length lenses.

12. A wafer alignment measurement method, the method comprising:
an illumination source; and
at least two variable focal length lenses, one positioned in an output channel and another positioned in an objective system, wherein the variable focal length lenses are controllable to control a height of focus of an output from the objective system.

13. The wafer alignment measurement method of claim 12, wherein an output of the illumination source is a radiation beam that reflects off a wafer.

14. The wafer alignment measurement method of claim 13, wherein the radiation beam passes through the variable focal length lenses after reflecting off the wafer.

15. The wafer alignment measurement method of claim 14, wherein there are “N” output channels and “N+1” variable focal length lenses, wherein there is one variable focal length lens in each output channel and one variable focal length lens in the objective system.
